(19) United States
(12) Patent Application Publication
(10) Pub. No.: US 2026/0004848 A1
(43) Pub. Date: Jan. 1, 2026

(54) DIFFERENTIAL WRITE AND READ FOR SELECTOR ONLY MEMORY

(71) Applicant: Sandisk Technologies, Inc., Milpitas, CA (US)

(72) Inventors: Mark Lin, Santa Clara, CA (US); Dimitri Houssameddine, Sunnyvale, CA (US)

(73) Assignee: Sandisk Technologies, Inc., Milpitas, CA (US)

(21) Appl. No.: 18/757,129

(22) Filed: Jun. 27, 2024

(51) Int. Cl. G11C 13/00

(52) U.S. Cl. CPC G11C 13/0069; G11C 13/0004; G11C 13/004; G11C 2013/0054

(57) ABSTRACT

Technology is disclosed for programming selector-only memory cells in a cross-point memory structure. The threshold switching memory element may include, but is not limited to, an Ovonic Threshold Switch (OTS). The memory system removes the effects of Vth drift in the reading of threshold switching memory elements. Each bit of data is written to a pair of selector-only memory cells with opposite polarities so that, when read with the same polarity, one has a high ON threshold and the other has a low ON threshold, but the bits are differentiated by which of the pair of selector-only memory cells has which ON threshold differs. Although the turn on voltage of both the high ON threshold state and the low ON threshold state drifts, they largely drift at the same rate so that a differential read of the memory cell pair can be used over an extended read period.

### BACKGROUND

Memory is widely used in various electronic devices such as cellular telephones, digital cameras, personal digital assistants, medical electronics, mobile computing devices, non-mobile computing devices, and data servers. Memory may comprise non-volatile memory or volatile memory. A non-volatile memory allows information to be stored and retained even when the non-volatile memory is not connected to a source of power (e.g., a battery).

The memory cells may reside in a cross-point memory array. In a memory array with a cross-point type architecture, one set of conductive lines run across the surface of a substrate and another set of conductive lines are formed above the other set of conductive lines running in an orthogonal direction relative to the initial layer. The memory cells are located at the cross-point junctions of the two sets of conductive lines. Cross-point memory arrays are sometimes referred to as cross-bar memory arrays.

One type of memory cell contains a programmable resistance memory element, such as magnetoresistive memory element. A magnetoresistive random access memory (MRAM) cell uses magnetization to represent stored data. A bit of data is written to an MRAM cell by changing the direction of magnetization of a magnetic element (“the free layer”) within the MRAM cell, and a bit is read by measuring the resistance of the MRAM cell, such resistance changing with the direction of magnetization. However, the cross-point memory array may have other types of memory cells. For example, the cross-point memory array may have memory cell of other technologies such as ReRAM, PCM (Phase Change Memory), or FeRAM.

In some cross-point memory architectures, each memory cell contains a threshold switching selector in series with a programmable resistance memory element. In such an architecture, the programmable resistance memory element is programmed to store data, whereas the threshold switching selector is used to select the memory cell. The threshold switching selector has a high resistance (in an off or non-conductive state) until it is biased to a voltage higher than its threshold voltage (Vt) or current above its threshold current, (It), and until its voltage bias falls below Vhold (“Voffset”) or current below a holding current Ihold. After the Vt is exceeded and while Vhold is exceeded across the threshold switching selector, the threshold switching selector has a relatively lower resistance (in an on or conductive state). The threshold switching selector remains on until its current is lowered below a holding current Ihold, or the voltage is lowered below a holding voltage, Vhold. When this occurs, the threshold switching selector returns to the off (higher) resistance state. One example of a threshold switching selector is an Ovonic Threshold Switch (OTS). Other examples of threshold switching selectors include, but are not limited to, Volatile Conductive Bridge (VCB), Metal-Insulator-Metal (MIM), or other material that provides a highly non-linear dependence of current on select voltage.

In some cross-point architectures, the memory cell contains a threshold switching selector that is used as both a selector and the programmable memory element. Such architectures may be referred to as either a selector only memory (SOM) cell or a self-selecting memory cell. The threshold voltage (Vth) of a SOM cell when reading with a voltage of a given polarity may depend on the polarity of the write voltage used to program the SOM cell. A SOM cell that is written and read with the same polarity voltage may exhibit a lower Vth than if the SOM cell is written and read with opposite polarity voltages. The memory system may assign a default polarity to the read voltage, which allows the SOM cell to be programmed to a first state using a first polarity write voltage and to a second state with a second polarity write voltage opposite the first polarity

However, over time the Vth of the threshold switching selector may drift, which presents technical challenges. FIG. 1A depicts a graph of threshold voltages of SOM cells over time. FIG. 1B is a table that shows a conventional programming scheme used in connection with the SOM cells. In this programming scheme state, WO is written with the same polarity voltage as the read voltage. However, state W1 is written with the opposite polarity voltage as the read voltage. Read may be performed with a default polarity voltage. The read voltage polarity may be selected by the memory system, but will be the same with each read. Column 60 shows the last voltage that applied to the memory cell, which resulted in the cell firing (e.g., switching on the selector). The up-arrows and down-arrows in the table in FIG. 1B are used to represent the relative polarities of the voltages. Column 62 shows the new data to be written to the cell.

Referring now to FIG. 1A, SOM cells programmed to state W0 (with “down-polarity write voltage”) and read immediately (with the “down-polarity read voltage”) will have a Vth near the star 20. SOM cells programmed to state W1 (with “up-polarity write voltage”) and read immediately (with the “down-polarity read voltage”) will have a Vth near the star 22. Plot 10 shows the upward drift in Vt of the W0 state cells. If read (with the down-polarity read voltage) after a significant time delay the W0 cells may have a Vth near the B level Vth, as indicated by arrow 30. If read (with the down-polarity read voltage) after a significant time delay the W1 cells may have a Vth near the A level Vth, as indicated by arrow 32. The Vth column 64 in the table of FIG. 1B summarizes the Vth of a particular cell, which depends on the relative polarity of the last fire voltage (column 60) and the polarity of the write voltage (column 62). Cells having a last fire of W1 and new data of W1 have the same polarity voltage for these two voltages; therefore, a write of the new data W1 sees a low Vth of B. However, cells having a last fire of W1 and new data of WO have opposite polarity voltages for these two voltages; therefore, a write of the new data W0 sees a high Vth of A. Cells having a last fire of W0 (or R0) and new data of W1 have the opposite polarity voltages for these two voltages; therefore, a write of the new data W1 sees a high Vth of A. Cells having a last fire of W0 (or R0) and new data of W0 have the same polarity voltages for these two voltages; therefore, write of the new data W0 sees a low Vth of B.

### BRIEF DESCRIPTION OF THE DRAWINGS

Like-numbered elements refer to common components in the different figures.

FIG. 1A depicts a graph of threshold voltages of SOM cells over time.

FIG. 1B is a table that shows a conventional programming scheme used in connection with the SOM cells.

FIG. 2 is a block diagram of one embodiment of a non-volatile memory system connected to a host.

FIG. 3A is a block diagram of one embodiment of a memory die.

FIG. 3B is a block diagram of one embodiment of an integrated memory assembly containing a control die and a memory structure die.

FIG. 4A depicts one embodiment of a portion of a memory array that forms a cross-point architecture in an oblique view.

FIGS. 4B and 4C respectively present side and top views of the cross-point structure in FIG. 4A.

FIG. 4D depicts an embodiment of a portion of a two-level memory array that forms a cross-point architecture in an oblique view.

FIG. 5 illustrates an embodiment for the structure of an SOM cell.

FIGS. 6A and 6B illustrate embodiments for the accessing a selected SOM cell in a cross-point memory structure.

FIG. 7 is a flowchart of one embodiment of a process of programming a two-terminal threshold switching selector memory cell in a cross-point array.

FIG. 8 depicts two “Vth distributions” for embodiment of programming a SOM cell.

FIG. 9 is a graph of the threshold voltage of an OTS versus the time lapse since the last firing of the memory cell and selection of a read voltage.

FIG. 10 illustrates a portion of a SOM cross-point array biased for a write operation.

FIGS. 11A-11C illustrate the read/write configuration for self-reference read in a SOM that uses two complimentary OTS devices to represent 1 bit.

FIG. 12 illustrates the differential response of the two complimentary OTS devices under the read arrangement of FIG. 11C when separate read currents are used for each OTS.

FIGS. 13 and 14 illustrate an alternate read-out embodiment in which both OTSs of a pair use the same constant read current.

FIG. 15 illustrates an embodiment for a read operation using a two-level, common bit line architecture for an OTS pair.

FIGS. 16A and 16 B illustrate an embodiment for the two steps of writing a “0” value in to the OTS pair of the selected memory cell the two level of the cross-point array portion illustrated in FIG. 15.

FIGS. 17A and 17B illustrate an embodiment for the two steps of writing a “1” value in to the OTS pair of the selected memory cell the two level of the cross-point array portion illustrated in FIG. 15.

FIG. 18 is an embodiment for a method of operating a cross-point array of self-selecting memory cells that store data bits in pairs of memory cells.

### DETAILED DESCRIPTION

Technology is disclosed for programming and reading selector-only memory cells in a cross-point memory structure. The threshold switching memory element may include, but is not limited to, an Ovonic Threshold Switch (OTS). In an embodiment, the memory system removes the effects of Vth drift in the reading of threshold switching memory elements. Each bit of data is written to a pair of selector-only memory cells with opposite polarities, so that, when read with the same polarity, one has a high ON threshold and the other has a low ON threshold, but the bits are differentiated by which of the pair of selector-only memory cells has which of the ON threshold. Although the turn on voltage of both the high ON threshold state and the low ON threshold state drifts, they largely drift at the same rate so that a differential read of the memory cell pair can be used over an extended read period.

The terms “top” and “bottom,” “upper” and “lower” and “vertical” and “horizontal,” and forms thereof, as may be used herein are by way of example and illustrative purposes only, and are not meant to limit the description of the technology inasmuch as the referenced item can be exchanged in position and orientation. Also, as used herein, the terms “substantially,” “approximately,” and/or “about” mean that the specified dimension or parameter may be varied within an acceptable tolerance for a given application.

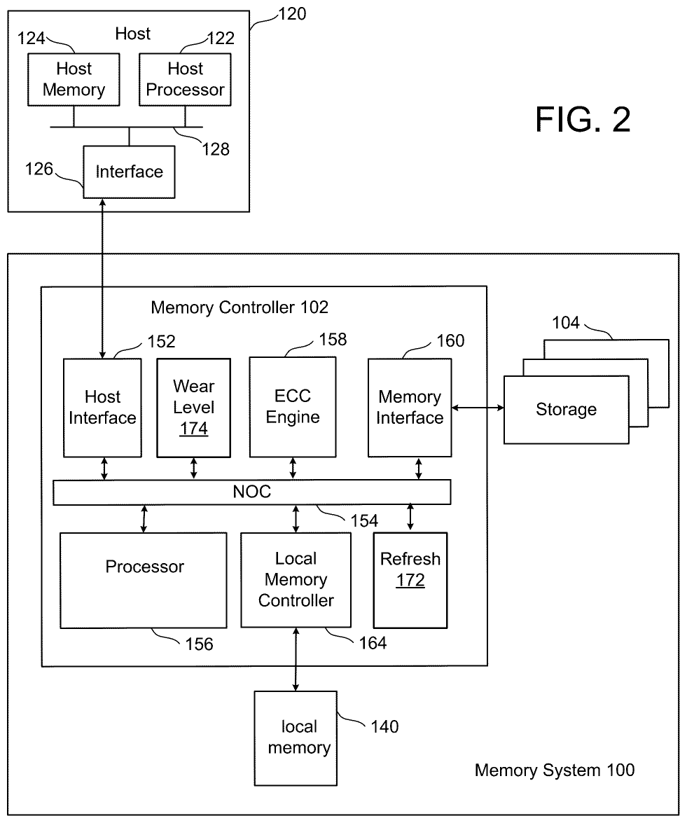

FIG. 2 is a block diagram of one embodiment of a non-volatile memory system (or more briefly “memory system”) 100 connected to a host system 120. In an embodiment, the memory cells have a threshold switching selector such as an OTS. Many types of memory systems can be used with the technology proposed herein. Example memory systems include dual in-line memory modules (DIMMs), solid state drives (“SSDs”), memory cards and embedded memory devices; however, other types of memory systems can also be used.

Memory system 100 of FIG. 2 comprises a memory controller 102, memory 104 for storing data, and local memory 140 (e.g., SOM, MRAM, ReRAM, DRAM). The local memory 140 may be non-volatile and retain data after power off. The local memory 140 may be volatile and not be expected to retain data after power off. In one embodiment the local memory 140 contains SOM cells. In an embodiment, the local memory is not required to retain data after power-off. However, the local memory may retain data after power-off. In one embodiment, memory controller 102 and/or local memory controller 164 provides access to SOM cells in local memory 140. For example, memory controller 102 may provide for access in a cross-point array of SOM cells in local memory 140. In another embodiment the memory controller 102 or interface 126 or both are eliminated and the memory packages are connected directly to the host 120 through a bus such as DDRn. Or they are connected to a host memory management unit (MMU). In another instance, the memory controller 102 or portions are moved onto the memory 104 for direct connection of the Memory 104 to the Host, such as by providing parity bits, ECC, and wear level on the Memory 104 along with an DDRn interface to/from the host or MMU. The term memory system, as used throughout this document, is not limited to memory system 100. For example, the local memory 140 or the combination of local memory 140 and local memory controller 164 could be considered to be a memory system. Likewise, host memory 124 or the combination of host processor 122 and host memory 124 considered to be a memory system.

The components of memory system 100 depicted in FIG. 2 are electrical circuits. The memory controller 102 has host interface 152, processor 156, ECC engine 158, memory interface 160, local memory controller 164, refresh logic 172, and wear level 174. The host interface 152 is connected to and in communication with host 120. Host interface 152 is also connected to a network-on-chip (NOC) 154. A NOC is a communication subsystem on an integrated circuit. NOC's can span synchronous and asynchronous clock domains or use unclocked asynchronous logic. NOC technology applies networking theory and methods to on-chip communications and brings notable improvements over conventional bus and crossbar interconnections. NOC improves the scalability of systems on a chip (SoC) and the power efficiency of complex SoCs compared to other designs. The wires and the links of the NOC are shared by many signals. A high level of parallelism is achieved because all links in the NOC can operate simultaneously on different data packets. Therefore, as the complexity of integrated subsystems keep growing, a NOC provides enhanced performance (such as throughput) and scalability in comparison with previous communication architectures (e.g., dedicated point-to-point signal wires, shared buses, or segmented buses with bridges). In other embodiments, NOC 154 can be replaced by a bus. Connected to and in communication with NOC 154 is processor 156, ECC engine 158, memory interface 160, local memory controller 164, refresh logic 172, and wear level 174. Local memory controller 164 is used to operate and communicate with local high speed memory 140 (e.g., MRAM). In other embodiments, local high speed memory 140 can be DRAM, SRAM or another type of volatile memory.

ECC engine 158 performs error correction services. For example, ECC engine 158 performs data encoding and decoding of parity bits provided on or off the memory as part of the code word used for error correction of the data fetched from memory 140 or 104. In one embodiment, ECC engine 158 is an electrical circuit programmed by software. For example, ECC engine 158 can be a processor that can be programmed. In other embodiments, ECC engine 158 is a custom and dedicated hardware circuit without any software. In one embodiment, the function of ECC engine 158 is implemented by processor 156. In one embodiment, local memory 140 has an ECC engine with or without a wear level engine. In one embodiment, memory 104 has an ECC engine with or without a wear level engine.

Processor 156 performs the various controller memory operations, such as programming, erasing, reading, and memory management processes including wear level. A separate wear level 174 is depicted, but the wear level 174 may be implemented by processor 156. Also, refresh logic 172 is depicted, but the refresh may also be implemented by the processor 156. In one embodiment, processor 156 is programmed by firmware. In other embodiments, processor 156 is a custom and dedicated hardware circuit without any software. Processor 156 also implements a translation module, as a software/firmware process or as a dedicated hardware circuit. In many systems, the non-volatile memory is addressed internally to the storage system using physical addresses associated with the one or more memory die. However, the host system will use logical addresses to address the various memory locations. This enables the host to assign data to consecutive logical addresses, while the storage system is free to store the data as it wishes among the locations of the one or more memory dies. To implement this system, memory controller 102 (e.g., the translation module) performs address translation between the logical addresses used by the host and the physical addresses used by the memory die. One example implementation is to maintain tables (i.e., the L2P tables mentioned above) that identify the current translation between logical addresses and physical addresses. An entry in the L2P table may include an identification of a logical address and corresponding physical address. Although logical address to physical address tables (or L2P tables) include the word “tables” they need not literally be tables. Rather, the logical address to physical address tables (or L2P tables) can be any type of data structure. In some examples, the memory space of a storage system is so large that the local memory 140 cannot hold all of the L2P tables. In such a case, the entire set of L2P tables are stored in memory 104 and a subset of the L2P tables are cached (L2P cache) in the local high speed memory 140.

Memory interface 160 communicates with storage 104. In an embodiment, storage 104 contains SOM cells in a cross-point array. In an embodiment, storage 104 contains NAND memory cells. In one embodiment, memory interface provides a Toggle Mode interface. Other interfaces can also be used. In some example implementations, memory interface 160 (or another portion of controller 102) implements a scheduler and buffer for transmitting data to and receiving data from one or more memory die.

In one embodiment, local memory 140 has an ECC engine. Local memory 140 may be used to help perform other functions such as wear leveling. Further details of on-chip memory maintenance are described in U.S. Pat. No. 10,545,692, titled “Memory Maintenance Operations During Refresh Window,” and U.S. Pat. No. 10,885,991, titled “Data Rewrite During Refresh Window,” both of which are hereby incorporated by reference in their entirety. In an embodiment, the local memory 140 is synchronous. In an embodiment, the local memory 140 is asynchronous.

In one embodiment, storage 104 comprises a plurality of memory packages. Each memory package includes one or more memory dies. Therefore, memory controller 102 is connected to one or more memory dies. In one embodiment, the memory package can include types of memory, such as storage class memory (SCM) based on programmable resistance random access memory (such as SOM, ReRAM, MRAM, FeRAM or RRAM) or a phase change memory (PCM). In one embodiment, memory controller 102 provides access to memory cells in a cross-point array in a storage 104.

Memory controller 102 communicates with host system 120 via an interface 152 that implements a protocol such as, for example, Compute Express Link (CXL). Or such controller can be eliminated and the memory packages can be placed directly on the host bus, DDRn or CXL for examples. For working with memory system 100, host system 120 includes a host processor 122, host memory 124, and interface 126 connected along bus 128. Host memory 124 is the host's physical memory, and can be SOM, DRAM, SRAM, ReRAM, MRAM, non-volatile memory, or another type of storage. In an embodiment, host memory 124 contains a cross-point array of programmable resistance memory cells, with each memory cell comprising a threshold switching selector to serve as a SOM cell.

Host system 120 is external to and separate from memory system 100. In one embodiment, memory system 100 is embedded in host system 120. Host memory 124 may be referred to herein as a memory system. The combination of the host processor 122 and host memory 124 may be referred to herein as a memory system. In an embodiment, such host memory can be cross-point memory using SOM cells.

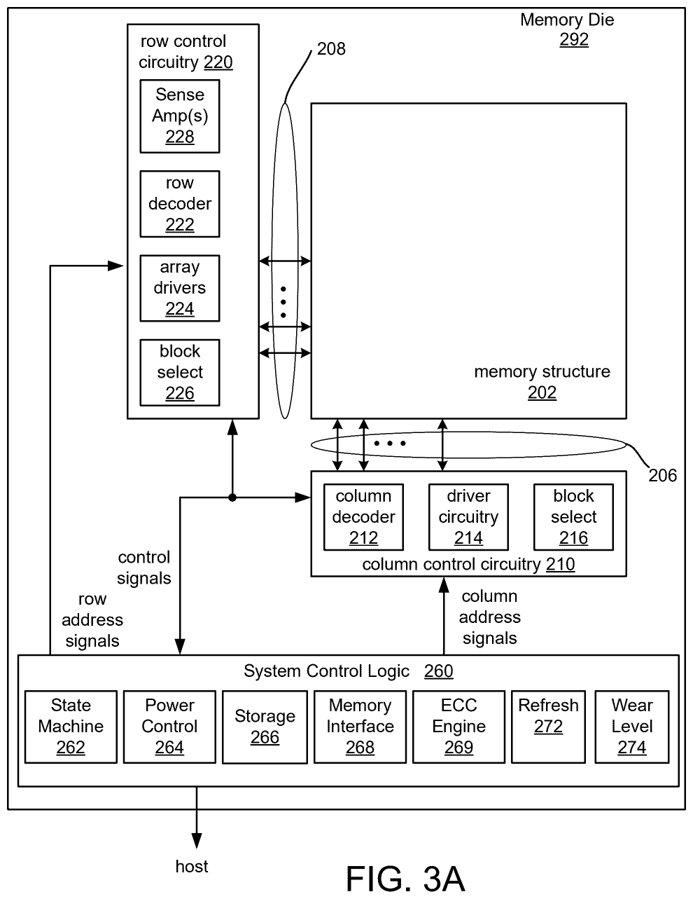

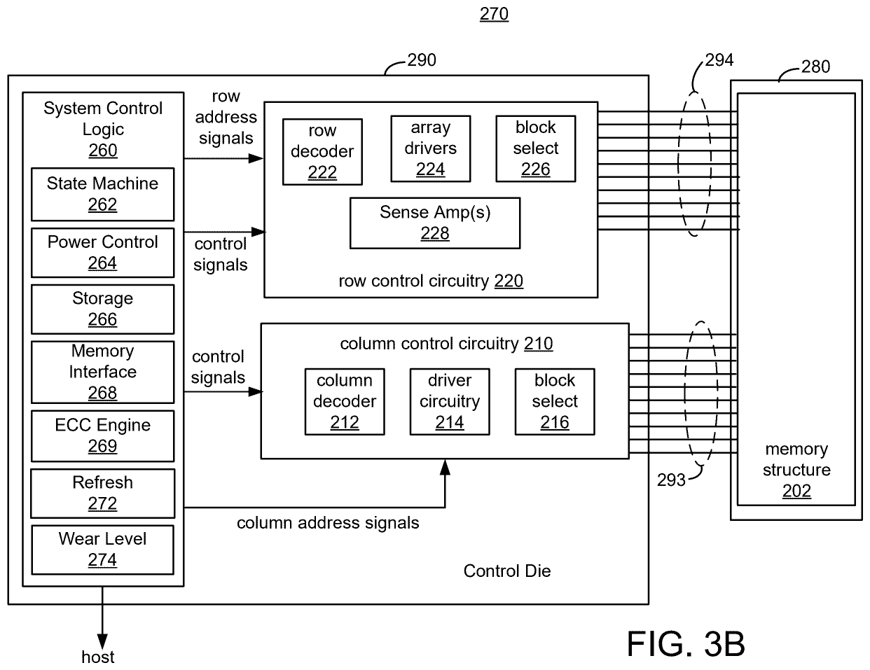

FIG. 3A is a block diagram that depicts one example of a memory die 292 that can implement the technology described herein. In one embodiment, memory die 292 is included in local memory 140, and in embodiment memory die 292 is included in storage 104. In one embodiment, memory die 292 is included in host memory 124. Memory die 292 includes a memory structure 202 that can include any of memory cells described in the following. The memory structure 202 may include one or more memory arrays. The array terminal lines of memory structure 202 include the various layer(s) of word lines organized as rows, and the various layer(s) of bit lines organized as columns. However, other orientations can also be implemented, including for example diagonal patterns to save space. Memory die 292 includes row control circuitry 220, whose outputs 208 are connected to respective word lines of the memory structure 202. Row control circuitry 220 receives a group of M row address signals and one or more various control signals from System Control Logic circuit 260, and typically may include such circuits as row decoders 222, row drivers 224, and block select circuitry 226 for both reading and writing operations. Row control circuitry 220 may also include read/write circuitry. In an embodiment, row decode and control circuitry 220 has sense amplifiers 228, which each contain circuitry for sensing a condition (e.g., voltage) of a word line of the memory structure 202. In an embodiment, by sensing a word line voltage, a condition or bit state of a memory cell (e.g., SOM cell) in a cross-point array is determined, either directly by a sense amp comparing the accessed memory cell voltage with a reference voltage. Memory die 292 also includes column decode and control circuitry 210 whose input/outputs 206 are connected to respective bit lines of the memory structure 202. Although only a single block is shown for memory structure 202, a memory die can include multiple arrays or “tiles” that can be individually accessed. Column control circuitry 210 receives a group of N column address signals and one or more various control signals from System Control Logic 260, and typically may include such circuits as column decoders 212, column decoders and drivers 214, block select circuitry 216, as well as read/write circuitry, and I/O multiplexers.

System control logic 260 receives data and commands from a host system and provides output data and status to the host system. In other embodiments, system control logic 260 receives data and commands from a separate controller circuit and provides output data to that controller circuit, with the controller circuit communicating with the host system. Such controller system may implement an interface such as DDR, DIMM, CXL, PCIe and others. In another embodiment those data and commands are sent and received directly from the memory packages to the Host without a separate controller, and any controller needed is within each die or within a die added to a multi-chip memory package. In some embodiments, the system control logic 260 can include a state machine 262 that provides die-level control of memory operations. In one embodiment, the state machine 262 is programmable by software. In other embodiments, the state machine 262 does not use software and is completely implemented in hardware (e.g., electrical circuits). In another embodiment, the state machine 262 is replaced by a micro-controller or microprocessor. The system control logic 260 can also include a power control module 264 that controls the power, current source currents, and voltages supplied to the rows and columns of the memory structure 202 during memory operations and may include charge pumps and regulator circuit for creating regulating voltages, and on/off control of each for word line bit line selection of the memory cells. In some embodiments, the power control 264 includes one or more current sources. The current source(s) may be used to provide read and/or write currents. System control logic 260 includes storage 266, which may be used to store parameters for operating the memory structure 202. System control logic 260 also includes refresh logic 272 and wear leveling logic 274. Such system control logic may be commanded by the host 120 or memory controller 102 to refresh logic 272, which may load an on-chip stored row and column address (Pointer) which may be incremented after refresh. Such address bit(s) may be selected only (to refresh the OTS). Or such address may be read, corrected by steering through ECC engine 269, and then stored in a “spare” location, which is also being incremented (so all codewords are periodically read, corrected, and relocated in the entire chip under control of wear leveling logic 274) to in effect wear level so use of each bit across the chip is more uniform. Such operation may be more directly controlled by the host of an external controller, for example a PCIe or CXL or DDRn controller located separately from the memory chip or on the memory die.

Commands and data are transferred between memory controller 102 and the memory die 292 via memory controller interface 268 (also referred to as a “communication interface”). Such interface may be PCIe, CXL, DDRn for example. Memory controller interface 268 is an electrical interface for communicating with memory controller 102. Examples of memory controller interface 268 also include a Toggle Mode Interface. Other I/O interfaces can also be used. For example, memory controller interface 268 may implement a Toggle Mode Interface that connects to the Toggle Mode interfaces of memory interface 228/258 for memory controller 102. In one embodiment, memory controller interface 268 includes a set of input and/or output (I/O) pins that connect to the controller 102. In another embodiment, the interface is JEDEC standard DDRn or LPDDRn, such as DDR5 or LPDDR5, or a subset thereof with smaller page and/or relaxed timing.

System control logic 260 located in a controller on the memory die in the memory packages may include Error Correction Code (ECC) engine 269. ECC engine 269 may be referred to as an on-die ECC engine, as it is on the same semiconductor die as the memory cells. That is, the on-die ECC engine 269 may be used to encode data and parity bits that are to be stored in the memory structure 202, and to decode the decoded data and correct errors. The encoded data may be referred to herein as a codeword or as an ECC codeword. ECC engine 269 may be used to perform a decoding algorithm and to perform error correction. Hence, the ECC engine 269 may decode the ECC codeword. In an embodiment, the ECC engine 269 is able to decode the data more rapidly by direct decoding without iteration. Having the ECC engine 269 on the same die as the memory cells allows for faster decoding. The ECC engine 269 can use a wide variety of decoding algorithms including, but not limited to, Reed Solomon, a Bose-Chaudhuri-Hocquenghem (BCH), and low-density parity check (LDPC).

In some embodiments, all of the elements of memory die 292, including the system control logic 260, can be formed as part of a single die. In other embodiments, some or all of the system control logic 260 can be formed on a different die, e.g., external controller chip.

In one embodiment, memory structure 202 comprises a three-dimensional memory array of non-volatile or volatile memory cells in which multiple memory levels are formed above a single substrate, such as a wafer. The memory structure may comprise any type of non-volatile or volatile memory that are monolithically formed in one or more physical levels of memory cells having an active area disposed above a silicon or silicon on insulator (or other type of) substrate. In another embodiment, memory structure 202 comprises a two-dimensional memory array of non-volatile memory cells.

The exact type of memory array architecture or memory cell included in memory structure 202 is not limited to the examples above. Many different types of memory array architectures or memory technologies can be used to form memory structure 202. No particular non-volatile memory technology is required for purposes of the newly claimed embodiments proposed herein. Examples of suitable technologies for memory cell architectures of the memory structure 202 include two dimensional arrays, three dimensional arrays, cross-point arrays, stacked two dimensional arrays, vertical bit line arrays, and the like.

One example of a SOM cross-point memory includes an OTS selector/memory element arranged in cross-point arrays accessed by X lines and Y lines (e.g., word lines and bit lines). In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

In some embodiments, the memory structure contains phase change memory (PCM). Phase change memory (PCM) exploits the unique behavior of chalcogenide glass. One embodiment uses a GeTe-Sb2Te3 super lattice to achieve non-thermal phase changes by simply changing the co-ordination state of the Germanium atoms with a laser pulse (or light pulse from another source). The memory cells are programmed by current pulses that can change the co-ordination of the PCM material or switch it between amorphous and crystalline states. Note that the use of “pulse” in this document does not require a square pulse but includes a (continuous or non-continuous) vibration or burst of sound, current, voltage, light, or other wave. And the current forced for a write can, for example, be driven rapidly to a peak value and then linearly ramped lower with, for example, a 500 ns edge rate. Such peak current force may be limited by a zoned voltage compliance that varies by position of the memory cell along the word line or bit line. In an embodiment, a phase change memory cell has a phase change memory element in series with a threshold switching selector such as an OTS.

A person of ordinary skill in the art will recognize that the technology described herein is not limited to a single specific memory structure, memory construction or material composition, but covers many relevant memory structures within the spirit and scope of the technology as described herein and as understood by one of ordinary skill in the art.

The elements of FIG. 3A can be grouped into two parts, the memory structure 202 and the peripheral circuitry, including all of the other elements. An important characteristic of a memory circuit is its capacity, which can be increased by increasing the area of the memory die 292 that is given over to the memory structure 202; however, this reduces the area of the memory die available for the peripheral circuitry or increases cost which is related to chip area. This can place quite severe restrictions on these peripheral elements. For example, the need to fit sense amplifier circuits within the available area can be a significant restriction on sense amplifier design architectures. With respect to the system control logic 260, reduced availability of area can limit the available functionalities that can be implemented on-chip. Consequently, a basic trade-off in the design of a memory die 292 is the amount of area to devote to the memory structure 202 and the amount of area to devote to the peripheral circuitry. Such tradeoffs may result in more IR drop from use of larger x-y arrays of memory between driving circuits on the word line and bit line, which in turn may benefit more from use of voltage limit and zoning of the voltage compliance by memory cell position along the word line and bit line.

Another area in which the memory structure 202 and the peripheral circuitry are often at odds is in the processing involved in forming these regions, since these regions often involve differing processing technologies and the trade-off in having differing technologies on a single die. For example, elements such as sense amplifier circuits, charge pumps, logic elements in a state machine, and other peripheral circuitry in system control logic 260 often employ PMOS devices. In some cases, the memory structure will be based on CMOS devices. Processing operations for manufacturing a CMOS die will differ in many aspects from the processing operations optimized for NMOS-only technologies.

To improve upon these limitations, embodiments described below can separate the elements of FIG. 3A onto separately formed die that are then bonded together. FIG. 3B depicts an integrated memory assembly 270 having a memory structure die 280 and a control die 290. The memory structure 202 is formed on the memory structure die 280 and some or all of the peripheral circuitry elements, including one or more control circuits, are formed on the control die 290. For example, a memory structure die 280 can be formed of just the memory elements, such as the array of SOM cells, or other memory type. Some or all of the peripheral circuitry, even including elements such as decoders, current sources, and sense amplifiers, can then be moved on to the control die. This allows each of the semiconductor die to be optimized individually according to its technology. This allows more space for the peripheral elements, which can now incorporate additional capabilities that could not be readily incorporated were they restricted to the margins of the same die holding the memory cell array. The two die can then be bonded together in a bonded multi-die integrated memory assembly, with the array on the one die connected to the periphery elements on the other die. Although the following will focus on an integrated memory assembly of one memory die and one control die, other embodiments can use additional die, such as two memory die and one control die, for example.

As with memory die 292 of FIG. 3A, the memory structure die 280 in FIG. 3B includes a memory structure 202 that can include multiple independently accessible arrays or “tiles.” System control logic 260, row control circuitry 220, and column control circuitry 210 are located in control die 290. In some embodiments, all or a portion of the column control circuitry 210 and all or a portion of the row control circuitry 220 are located on the memory structure die 280. In some embodiments, some of the circuitry in the system control logic 260 is located on the on the memory structure die 280.

FIG. 3B shows column control circuitry 210 on the control die 290 coupled to memory structure 202 on the memory structure die 280 through electrical paths 293. For example, electrical paths 293 may provide electrical connection between column decoder 212, column driver circuitry 214, and block select 216 and bit lines of memory structure 202. Electrical paths may extend from column control circuitry 210 in control die 290 through pads on control die 290 that are bonded to corresponding pads of the memory structure die 280, which are connected to bit lines of memory structure 202. Each bit line of memory structure 202 may have a corresponding electrical path in electrical paths 293, including a pair of bond pads, which connects to column control circuitry 210. Similarly, row control circuitry 220, including row decoder 222, row drivers 224, block select 226, and sense amplifiers 228 are coupled to memory structure 202 through electrical paths 294. Each of electrical path 294 may correspond to, for example, a word line. Additional electrical paths may also be provided between control die 290 and memory structure die 280.

For purposes of this document, the phrase “a control circuit” can include one or more of memory controller 102, local memory controller 164, processor 156, system control logic 260, column control circuitry 210, row control circuitry 220, host processor 122, a micro-controller, a state machine, and/or other control circuitry, or other analogous circuits that are used to control non-volatile memory. The control circuit can include hardware only or a combination of hardware and software (including firmware). For example, a controller programmed by firmware to perform the functions described herein is one example of a control circuit. A control circuit can include a processor, FPGA, ASIC, integrated circuit, or other type of circuit. Such control circuitry may include drivers such as direct drive via connection of a node through fully on transistors (gate to the power supply) driving to a fixed voltage such as a power supply. Such control circuitry may include a current source driver.

For purposes of this document, the term “apparatus” can include, but is not limited to, one or more of memory system 100, local memory 140, the combination of local memory controller 164 and/or memory controller 102 and local memory 140, storage 104, memory die 292, integrated memory assembly 270, and/or control die 290.

In the following discussion, the memory structure 202 of FIGS. 3A and 3B will be discussed in the context of a cross-point architecture. In a cross-point architecture, a first set of conductive lines or wires, such as word lines, run in a first direction relative to the underlying substrate and a second set of conductive lines or wires, such a bit lines, run in a second direction relative to the underlying substrate. The memory cells are sited at the intersection of the word lines and bit lines. The memory cells at these cross-points can be formed according to any of a number of technologies, including those described above. The following discussion will mainly focus on embodiments based on a cross-point architecture using SOM cells, each having a threshold switching selector such as Ovonic Threshold Switch (OTS) to comprise a selectable memory bit. However, embodiments are not limited to the selector being an OTS.

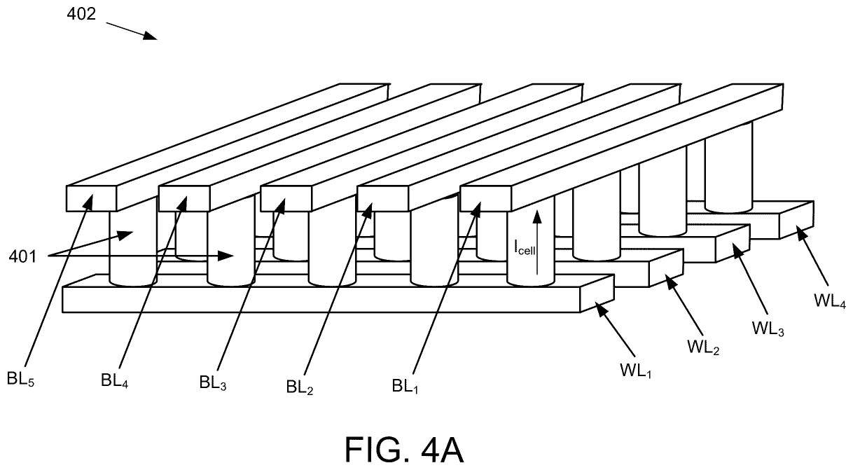

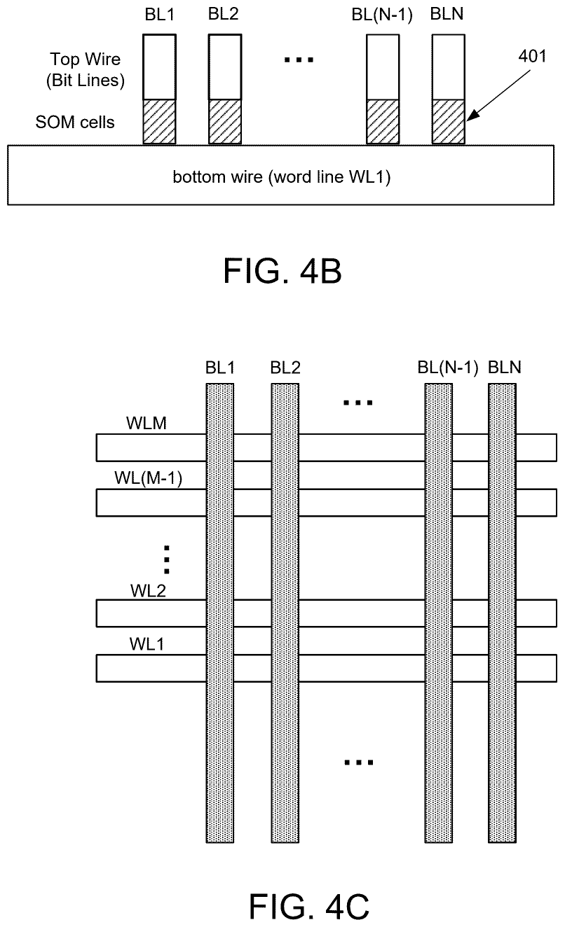

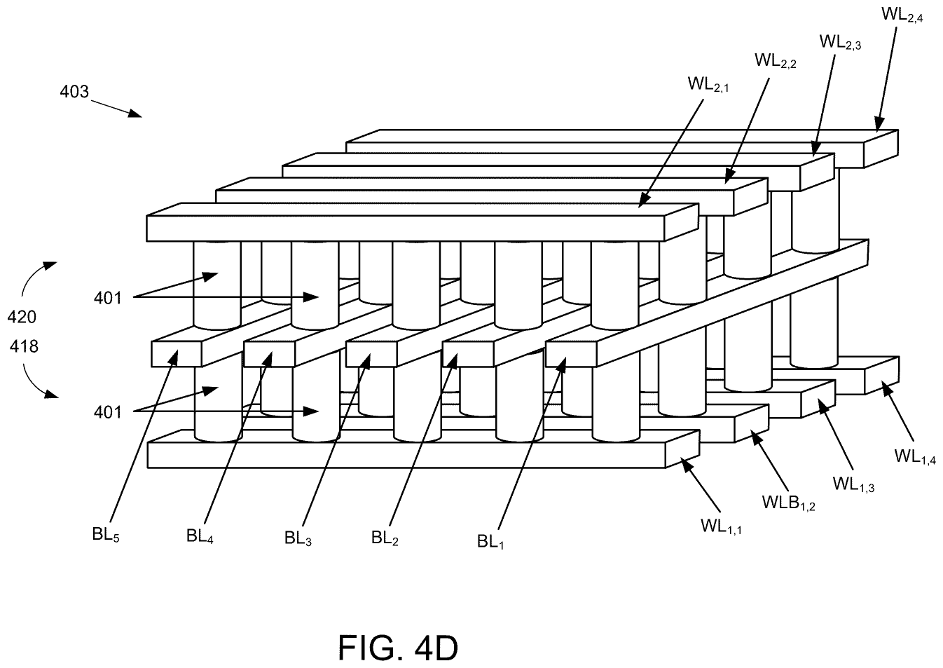

FIG. 4A depicts one embodiment of a portion of a memory array 402 that forms a cross-point architecture in an oblique view. Memory array 402 of FIG. 4A is one example of an implementation for memory structure 202 in FIG. 3A or 3B, where a memory die 292 or memory structure die 280 can include multiple such memory arrays 402. The memory array 402 may be included in local memory 140 or host memory 124. The bit lines BL₁-BL₅ are arranged in a first direction (represented as running into the page) relative to an underlying substrate (not shown) of the die and the word lines WL₁-WL₅ are arranged in a second direction perpendicular to the first direction, or diagonal to provide intersections where memory cells are interconnected between WLs and BLs. FIG. 4A is an example of a horizontal cross-point structure in which word lines WL₁-WL₅ and BL₁-BL₅ both run in a horizontal direction relative to the substrate, while the memory cells, two of which are indicated at 401, are oriented so that the current through a memory cell (such as shown at I_{cell}) runs in the vertical direction. In a memory array with additional layers of memory cells, such as discussed below with respect to FIG. 4D, there would be corresponding additional layers of bit lines and word lines. One pattern, for example, would be from the bottom layer: WL, memory cell, BL, memory cell, WL, WL, memory cell, BL memory cell, WL.

As depicted in FIG. 4A, memory array 402 includes a plurality of memory cells 401. The memory cells 401 may include re-writeable memory elements, such as can be implemented using a threshold switching selector, which may be operated to have a programmable resistance. The memory cells 401 may be referred to herein as programmable resistance memory cells. The memory cells 401 may also be referred to herein as self-selecting memory cells or selector only memory cells. The threshold switching selectors can be implemented using an Ovonic Threshold Switch (OTS), Volatile Conductive Bridge (VCB), Metal-Insulator-Metal (MIM), or other material that provides a highly non-linear dependence of current or resistance for varying select voltage. The following discussion will focus on memory cells composed of an OTS memory element, although much of the discussion can be applied more generally. The current in the memory cells of the first memory level is shown as flowing upward as indicated by arrow I_{cell}, but current can flow in either direction to either read or write the memory cell bit state, as is discussed in more detail in the following.

FIGS. 4B and 4C respectively present side and top views of the cross-point structure in FIG. 4A. The sideview of FIG. 4B shows one bottom wire, or word line, WL₁ and the top wires, or bit lines, BL₁-BLₙ. At the cross-point between each top wire and bottom wire is a SOM memory cell 401. FIG. 4C is a top view illustrating the cross-point structure for M bottom wires WL₁-WL_{M} and N top wires BL₁-BL_{N}. In a binary embodiment, the SOM cell at each cross-point can be programmed into one of two resistance states: high and low. More detail on embodiments for an SOM memory cell design and techniques for their programming are given below. In some embodiments, sets of these wires are arrayed continuously as a “tile,” and such tiles may be paired adjacently in the Word Line (WL) direction and orthogonally in the Bit Line direction to create a module. Such a module may be composed of 2×2 tiles to form a four tile combination wherein the WL drivers between the tiles is “center driven” between the tiles with the WL running continuously over the transistor driver at the approximate center of the line. Similarly, BL drivers may be located between the pair of tiles paired in the BL direction to be center driven, whereby the transistor driver and its area is shared between a pair of tiles. Vias of copper or other types of low resistance may decode and connect the transistor driver/selects to the WL or BL. In addition to the memory element in the memory cell between WL and BL may also be included a series select element such as an OTS.

The cross-point array of FIG. 4A illustrates an embodiment with one layer of word lines and bits lines, with the SOM or other memory technology for the memory cells sited at the intersection of the two sets of conducting lines. To increase the storage density of a memory die, multiple layers of such memory cells and conductive lines can be formed. A two-layer example is illustrated in FIG. 4D.

FIG. 4D depicts an embodiment of a portion of a two-level memory array that forms a cross-point architecture in an oblique view. As in FIG. 4A, FIG. 4D shows a first layer 418 of memory cells 401 of a memory array 403 connected at the cross-points of the first layer of word lines WL_{1,1}-WL_{1,4} and bit lines BL₁-BL₅ above. Memory array 403 may be included in memory structure 202 of FIG. 3A or 3B. A second layer 420 of memory cells is formed above the bit lines BL₁-BL₅ and between these bit lines and a second set of word lines WL_{2,1}-WL_{2,4}. In effect the BLs are shared. In the alternative a second layer may include another deck of BL above the BL shown and below the 2^{nd} deck of WL. Although FIG. 4D shows two layers, 418 and 420, of memory cells, the structure can be extended upward through additional alternating layers of word lines and bit lines in a similar pattern. Depending on the embodiment, the word lines and bit lines of the array of FIG. 4D can be biased for read or program operations such that current in each layer flows from the word line layer to the bit line layer or the other way around. The two layers can be structured to have current flow in the same direction in each layer for a given operation or to have current flow in the opposite directions by driver selection in the positive or negative direction. The memory cell may be placed in the same orientation within the first and second layers enabling use of current in oppositive directions by layer to read or write. Or the memory cell placed in a reversed or flipped direction when placed between the BL and WL in the second layer (enabling use of current in the same direction as is used to read or write in memory cells within the first layer. As will be apparent to someone reasonably skilled in the art, the two layers can be extended to three or more layers.

The use of a cross-point architecture allows for arrays with a small footprint and several such arrays can be formed on a single die. The memory cells formed at each cross-point can be a resistive type of memory cell, where data values are encoded as different resistance levels. Depending on the embodiment, the memory cells can be binary valued, having either a low resistance state or a high resistance state, or multi-level cells (MLCs) that can have additional resistance intermediate to the low resistance state and high resistance state. The cross-point arrays described here can be used in the memory die 292 of FIG. 3A, the local memory 140 in FIG. 2, and/or the host memory 124 in FIG. 2, or in any other configuration where additional memory is useful. Resistive type memory cells can be formed according to many of the technologies mentioned herein, such as OTS. The following discussion is presented mainly in the context of memory arrays using a cross-point architecture with binary valued OTS memory cells, although much of the discussion is more generally applicable to other memory elements in memory cells within a cross-point array or other configurations apparent to those reasonably skilled in the art.

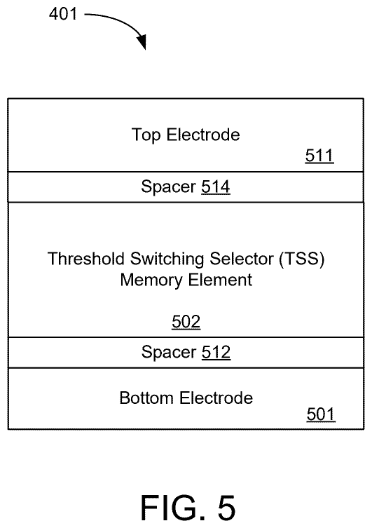

FIG. 5 illustrates the structure of an embodiment for an SOM cell. The SOM cell 401 may be used as the programmable resistance memory cell 401 in, for example, FIGS. 4A-4D. The SOM cell includes a bottom electrode 501, spacer 512, a threshold switching selector (TSS) memory element 502, spacer 514, and a top electrode 511. In some embodiments, the bottom electrode 501 is a word line and the top electrode 511 is a bit line. In other embodiments, the bottom electrode 501 is a bit line and the top electrode 511 is a word line. The state of the memory cell is based on the state of the TSS memory element 502.

Data is written to an SOM memory cell by programming the TSS memory element 502 with a program (or write) signal (e.g., program current, program voltage) having a desired polarity. In one embodiment, the SOM memory cell is programmed to a first state (W0) using a first polarity program signal and to a second state (W1) using a second polarity program signal. The SOM memory cell may be read using a read signal (e.g., read current, read voltage). The polarity of the read signal relative to the polarity of the program signal may impact the Vth of the SOM cell. In an embodiment, a read signal having the same polarity as the program signal results in a lower Vth than a read signal having the opposite polarity as the program signal. Typically, the memory system will choose a polarity for the read signal and then be consistent with that polarity of read signal when determining the state of the SOM cell. Therefore, the polarity of the program signal will, in effect, result in a higher/lower Vth when read with the chosen polarity read signal.

The threshold switching selector 502 may also serve as a selector to select the memory cell for a memory operation. The threshold switching selector 502 has a high resistance (in an off or non-conductive state) until it is biased to a voltage higher than its threshold voltage (Vth) or current above its threshold current, and until its voltage bias falls below Vhold (also known as “Voffset”) or current below Ihold. After the Vth is exceeded and while Vhold is exceeded across the switching selector, the switching selector has a low resistance (in an on or conductive state). The threshold switching selector remains on until its current is lowered below a holding current Ihold, or the voltage is lowered below a holding voltage, Vhold. When this occurs, the threshold switching selector returns to the off (higher) resistance state. Accordingly, to select a memory cell at a cross-point, a voltage or current is applied which is sufficient to turn on the associated threshold switching selector. One set of examples for a threshold switching selector is an ovonic threshold switching material of an Ovonic Threshold Switch (OTS). Example threshold switching materials include Ge—Se, Ge—Se—N, Ge—Se—As, Ge—Se—Sb—N, Ge58Se42, GeTe₆, Si—Te, Zn—Te, C—Te, B—Te, Ge—As—Te—Si—N, Ge—As—Se—Te—Si and Ge—Se—As—Te, with atomic percentages ranging from a few percent to more than 90 percent for each element. In an embodiment, the threshold switching selector is a two terminal device. The threshold switching selector 502 can also contain additional conducting layers. For example, spacer 514 is depicted between switching selector 502 and top electrode 511. The spacer layer 514 can be a single conducting layer or composed of multiple conducting layers. The threshold switching selector 502 can also contain additional conducting layers on the interface with the bottom electrode 501. For example, spacer 512 is depicted between switching selector 502 and bottom electrode 501. The spacer layer 512 on the interface with bottom electrode 501 can be a single conducting layer or composed of multiple conducting layers. Examples of conducting layers adjacent to the OTS include carbon, carbon nitride, carbon silicide, carbon tungsten, titanium, titanium nitride, tungsten, tungsten nitride, tantalum, tantalum nitride, and others. Threshold voltage switches have a Threshold Voltage (Vt) above which the resistance of the device changes substantially from insulating, or quasi insulating, to conducting.

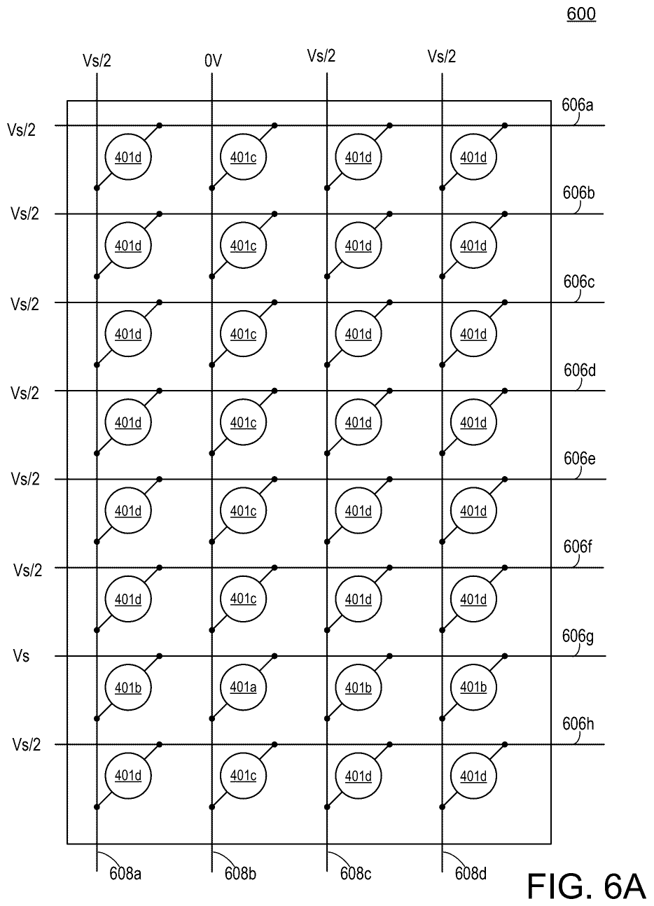

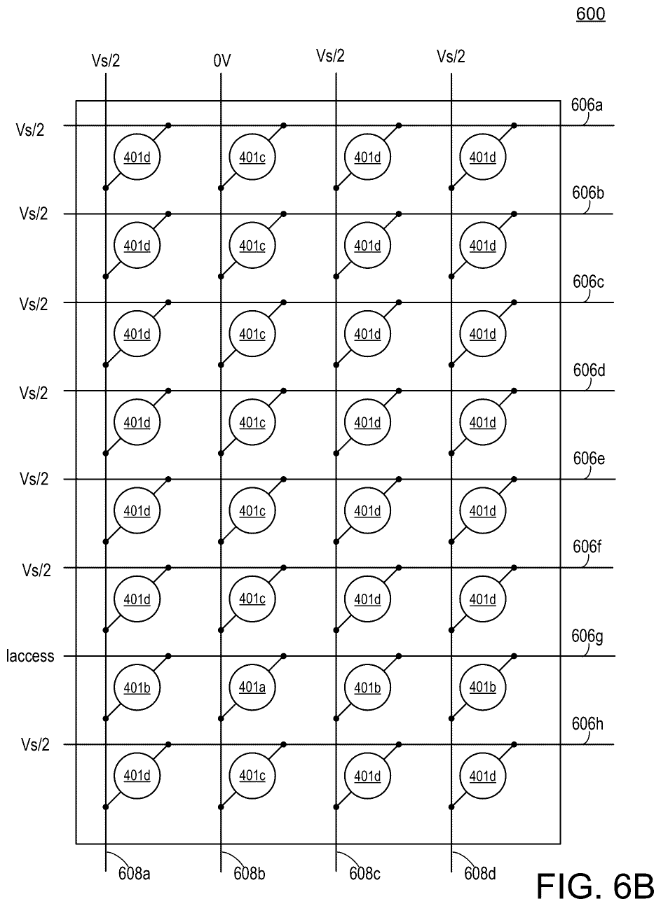

FIG. 6A depicts an embodiment of a memory array 600 having a cross-point architecture. The memory array 600 may be included in memory structure 202 of FIG. 3A or 3B. The array 600 has a set of first conductive lines 606a-606h and a set of second conductive lines 608a-608d. In one embodiment, the set of first conductive lines 606a-606h are word lines and the set of second conductive lines 608a-608b are bit lines. For ease of discussion, the set of first conductive lines 606a-606h may be referred to as word lines and the set of second conductive lines 608a-608b may be referred to as bit lines. However, the set of first conductive lines 606a-606h could be bit lines and the set of second conductive lines 608a-608b could be word lines.

The memory array 600 has a number of programmable resistance memory cells 401. The programmable resistance memory cells 401 may be referred to as self-selecting memory cells or selector-only memory cells. In an embodiment, each cell 401 has a structure similar to the cell in FIG. 5. Each memory cell 401 is connected between one of the first conductive lines 606 and one of the second conductive lines 608 (e.g., at the cross point of one of the first conductive lines 606 and one of the second conductive lines 608). Each SOM cell 401 has a threshold switching selector (not depicted in FIG. 6A). The threshold switching selector 502 becomes conductive in response to application of a voltage level exceeding a threshold voltage of the threshold switching selector 502, and remains conductive with lower resistance until the current through the switching selector 502 is reduced below the selector holding current, Ihold. The threshold switching selector 502 may be a two terminal device. In an embodiment, the threshold switching selector 502 comprises an OTS.

Techniques are disclosed for programming SOM cells. For purpose of discussion, memory cell 401a is being selected for a memory operation such as read or write. An example of programming the threshold switching selector 502 will be discussed. Selected memory cell 401a is at the cross-point of selected word line 606g and selected bit line 608b. A selected memory cell means a memory cell that is selected for a memory operation such as read or write. A selected memory cell is connected between a selected word line and a selected bit line. In an embodiment, to program a selected memory cell 401, a select voltage such as near ground is provided to the selected bit line (e.g., bit line 608b) and program (or write) voltage (Vs) is applied to a selected word line (e.g., word line 606g). A selected word line means that the word line is connected to at least one selected memory cell. Alternatively, the memory cell could be selected by applying the program voltage (Vs) to the selected bit line while applying a select voltage to the selected word line.

In one approach word lines that are not connected to the selected memory cell may be driven by a voltage that is approximately one-half the magnitude of the voltage across the selected cell. As depicted in FIG. 6A, word lines 606a, 606b, 606c, 606d, 606e, 606f, and 606h each have what is referred to as a half-select voltage (Vs/2) applied thereto. The half-select voltage (Vs/2) has approximately one-half the magnitude of the voltage across the selected cell (Vs). For programming, the voltage Vs may be referred to as a program voltage. For example, the voltage Vs may be referred to as a read voltage.

In one approach bit lines that are not connected to the selected memory cell may be driven by a voltage that is approximately one-half the magnitude of the voltage across the selected cell. As depicted in FIG. 6A, bit lines 608a, 608c, and 608d each have what is referred to as a half-select voltage (Vs/2) applied thereto. As noted above, the half-select voltage (Vs/2) has approximately one-half the magnitude of the voltage across the selected cell (Vs).

Some of the memory cells connected to the selected word line are what is referred to herein as half-selected memory cells. The voltage across a half-selected memory cell is approximately half of the voltage across a selected memory cell. The half-selected memory cells 401b connected to the selected word line each have Vs applied to the selected word line and Vs/2 applied to their respective bit lines. Therefore, half-selected memory cells 401b each have Vs/2 applied across the memory cell.

Some of the memory cells connected to the selected bit line are what is referred to herein as half-selected memory cells. The voltage across these half-selected memory cell is approximately half of the voltage across the selected memory cell. The half-selected memory cells 401c connected to the selected bit line each have OV applied to the selected bit line and Vs/2 applied to their respective word lines. Therefore, half-selected memory cells 401c each have Vs/2 applied across the memory cell.

The threshold switching selector 502 in such half-selected memory cells 401b, 401c should not turn on during operations such as read or write. However, if the Vth of the threshold switching selector 502 is less than Vs/2 then the threshold switching selector 502 could turn on during a memory operation. Techniques are disclosed herein for preventing (or at least reducing the chance of) the threshold switching selectors 502 in half-selected memory cells 401b, 401c from turning on during a memory operation such as read or write. In an embodiment, Vth drift is removed from memory cells prior to programming, which allows the program voltage to have a lower magnitude. Using a lower magnitude for the program voltage will lower the magnitude of Vs/2, which reduces the probability of inadvertent selection of a half-selected memory cell.

Other memory cells are fully unselected by which it is meant they have approximately 0V across the memory cell. The fully unselected memory cells 401d are pointed out in FIG. 6A. In this example, each fully unselected memory cell 401d has Vs/2 applied to its word line and Vs/2 applied to its bit line.

In the example of FIG. 6A there are more word lines than bit lines in the cross-point array. In another embodiment, there are more bit lines than word lines in the cross-point array. In another embodiment, the number of bit lines equals the number of word lines in the cross-point array. In the example of FIG. 6A there are twice as many word lines as bit lines in the cross-point array; however, a different ratio could be used. Thereby, different tile sizes may be realized. For example, a tile may have 1024 BL by 2048 WL, which may be composed into a module of 2048×4096 cells by center driving the WL and BL between the four tiles. In one embodiment, read is performed on a group of memory cell by, for example, selecting one memory cell in each of a number of tiles. In some embodiments, more than one memory cell from a tile may be selected for a read.

FIG. 6A is shown and described as using a voltage-force approach in which a voltage is provided to the selected word line. In an embodiment, a current-force approach is used to access the SOM cell. The current-force approach may be used to read or write the SOM cell. FIG. 6B depicts an example of a current-force approach. In the current-force approach, an access current (e.g., I_{access}) is driven to the selected word line (or sunk from the selected word line, depending on the direction of I_{access}). The selected bit line may be held at ground. As a result the current charges up the voltage on the selected word line. In an embodiment, the maximum magnitude of the selected word line voltage will be limited to Vs. Alternatively, the selected bit line may be held at a higher voltage, with the current being sunk from the selected word line. The unselected word lines and unselected bit lines have voltages applied thereto. The magnitudes of the voltages to the unselected word lines and unselected bit lines may be similar to the example in FIG. 6A. The half-select problems discussed in connection with the voltage-force approach may also occur in a current-force approach. Herein, a term such as program signal may include both a program voltage and a program current. Likewise, a term such as read signal may include both a read voltage and a read current.

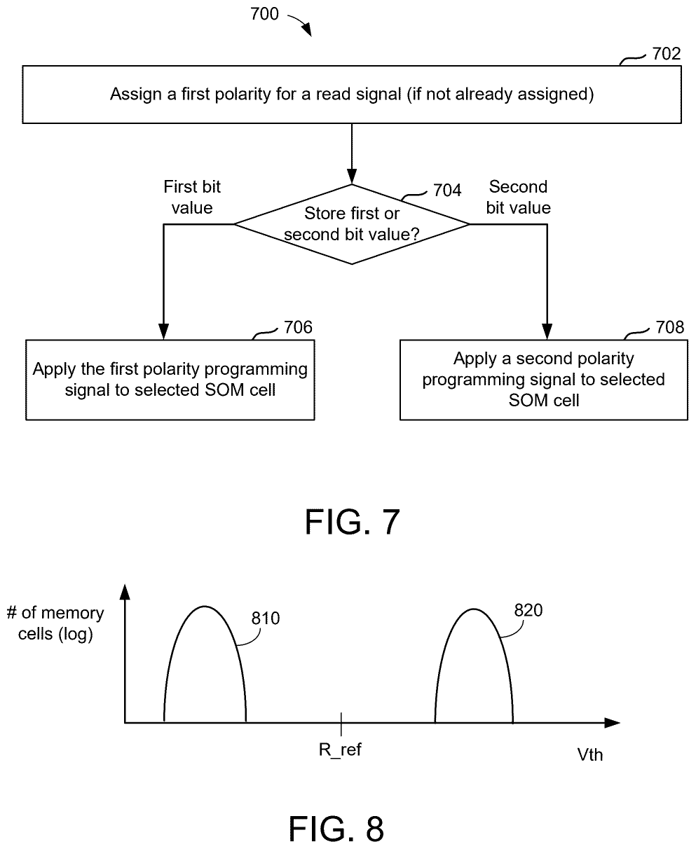

FIG. 7 is a flowchart of one embodiment of a process 700 of programming a SOM cell 401 in a cross-point array. The process 700 may be used to program a SOM cell 401 such as the one discussed in FIG. 5. In one embodiment, the SOM cell 401 includes an OTS that serves as the programmable resistance memory element. The process 700 may be performed on many memory cells in parallel, such as performing the process in selected memory cells in different tiles 600. In one embodiment, process 700 is performed by one or more control circuits such as, but not limited to, one or more of memory controller 102, system control logic 260, column control circuitry 210, row control circuitry 220, a micro-controller, a state machine, host processor 122 and/or other control circuitry, or other analogous circuits that are used to control non-volatile memory.

Step 702 includes choosing a first polarity for future read signals applied to the SOM cell 401. Step 702 can be omitted if the choice of first polarity has already been established and does not need to be changed. The first polarity can be positive or negative. The current polarity may be defined based on the voltage across the cell that is caused by the current. Here, positive or negative polarity may be defined with respect to, for example, the selected word line and the selected bit line.

Step 704 includes a determination of whether to store a first bit value or a second bit value into the SOM cell 401. As one example, the first bit value is “0” and the second bit value is “1”. As another example, the first bit value is “1” and the second bit value is “0.” However, the bit values could be reversed from this example.

If the first bit value is to be stored, then step 706 is performed. Step 706 includes applying a programming (or write) signal having the first polarity to the SOM cell 401 cell 401. Thus, the programming signal in step 706 has the same polarity as the read signal if the cell is read in the future.

If the second bit value is to be stored, then step 708 is performed. Step 708 includes applying a programming signal having a second polarity to the SOM cell 401. The second polarity is opposite to the first polarity. Thus, the programming signal in step 708 has the opposite polarity as a future read signal. In steps 702, 706, and 708 either a current-force or a voltage-force technique may be used to apply the signals.

FIG. 8 depicts example Vth distributions for a group of SOM cells 402 after programming using process 700. FIG. 8 depicts two “Vth distributions” for the SOM cell 401 as they would be measured when read with a read signal of the first polarity discussed in process 700. Vth distribution 810 represents SOM cells 401 that store a first bit value. Vth distribution 820 represents SOM cells 401 that store a second bit value. The vertical axis represents the numbers of memory cells and is a log scale. The horizontal axis represents the Vth of the threshold switching selector, assuming that the when the SOM cell 401 is read with a read voltage having the pre-assigned first polarity. A reference resistance R_ref is depicted between the two Vth distributions 810, 820. In an embodiment, R_ref is used to demarcate between the two Vth distributions. Note that if the SOM cells were instead to be read with a read signal having the second polarity, then the Vth distributions 810, 820 may be reversed.

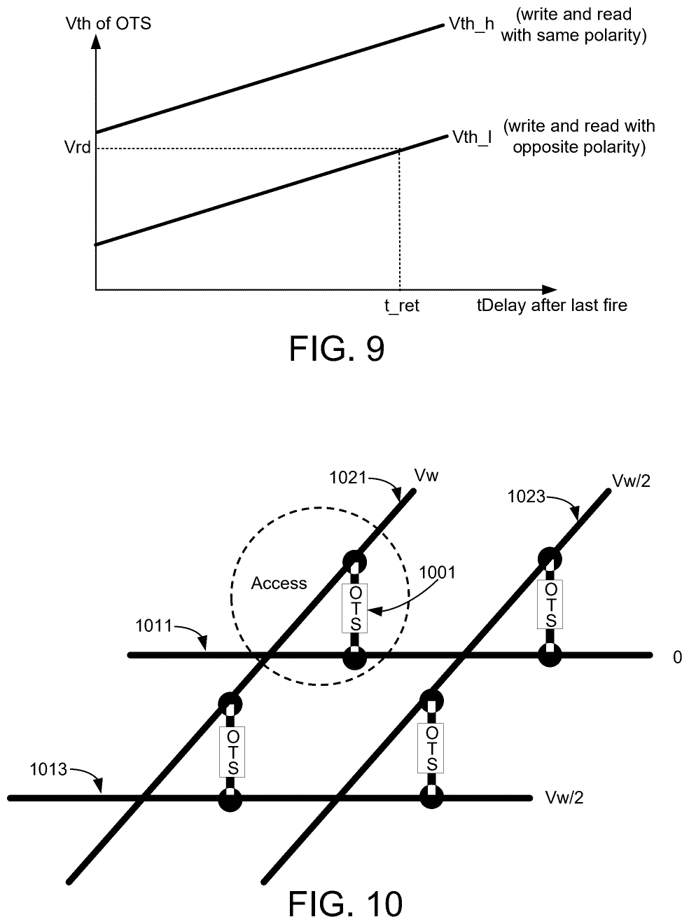

As presented above, in a SOM cross-point array type memory, each OTS has been used as the example selector to play two roles: a switch to select a bit in a cross-point array; and to store the binary information 0 or 1. An OTS switches from high-resistance state to low-resistance state when bias voltage is greater than Vth (threshold voltage). As discussed above, Vth is a function of 2 properties. Property (1) is that the current direction to switch-on the OTS in the 1^{st} time access determines the Vth requirement for the 2^{nd} access using a fixed current direction. The high threshold voltage, Vth_h, is when current direction for 1^{st} and 2^{nd} access are opposite to each other, while the low threshold voltage, Vth_l, is when both accesses have the same current direction. Property (2) is that Vth for either state drifts up as the time lapse between the 1^{st} and 2^{nd} time access increases. The property (1) is exploited to story binary information. Demarcation-read sets a constant voltage constant read voltage, Vrd, in between Vth_h and Vth_l and determines the binary data by sensing the resistance state. The property (2), however, erodes the read window for an array since, as the lapse time duration for each bits varies, so does the drift amount of Vth, as illustrated in FIG. 9.

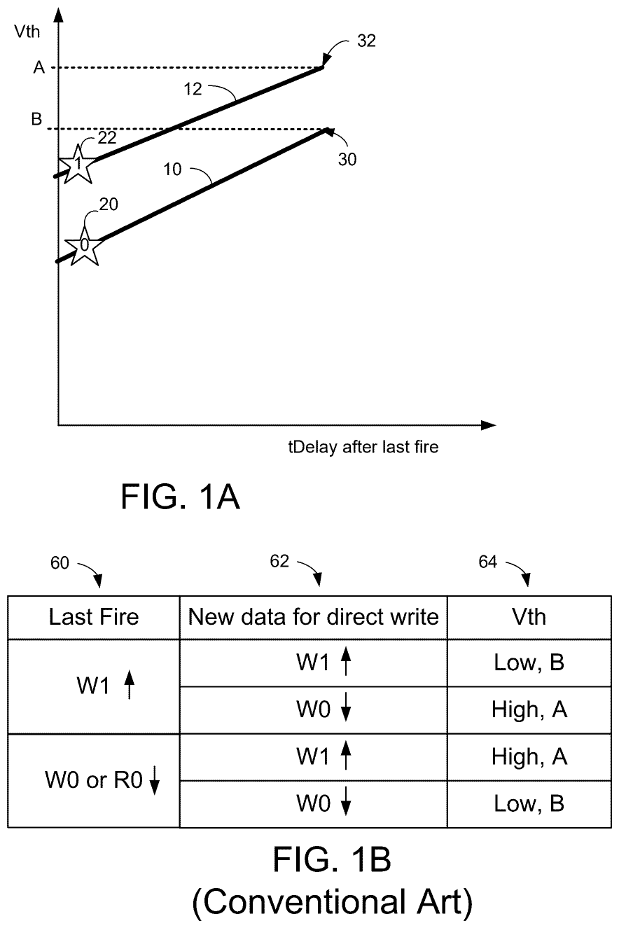

FIG. 9 is a graph of the threshold voltage of an OTS versus the time lapse (tDelay) since the last firing of the memory cell, arranged similarly to FIG. 1A. As illustrated in FIG. 9, the read voltage Vrd is set between the Vth_h and Vth_l values at tDelay=0 in order to be able to differentiate the two states, but near Vth_h to allow for Vth drift. The value t_ret represents the retention time when the read window diminishes. Therefore, to avoid data loss a re-write is needed to scrub all bits, resetting the lapse-time and maintaining the read bit error rate (BER).

FIG. 10 illustrates a portion of a SOM cross-point array biased for a write operation using the voltages of a write voltage Vw and the intermediate voltage Vw/2. In this example of SOM, two bit lines 1021 and 1023 and two word lines 1011 and 1013 are shown, with an OTS connected at each cross-point. OTS 1001 is selected for a write access, as described above with respect to FIG. 7. The write access for a bit in selected OTS 1001 is performed by applying write voltage Vw greater than Vth_h on bit line 1021 and ground on word line 1011. The rest of bit lines (e.g., 1023) and word lines (e.g., 1013) in the same array are set to Vw/2, which is selected to less than Vth_l to avoid half-selection disturb.

The following presents embodiments that address the data retention problem for SOM memories as limited by the Vth variability between bits and the drift rate, where this retention gets worse at higher temperatures when the drift rate soars. Lower retention requires a higher data refresh rate, which has a negative impact to data bandwidth and an increase on power consumption. In addition to increasing data refresh rates, other previous approaches to minimize the drift rate have included engineering the OTS material, which typically is of limited success.

To overcome these limitations, the following embodiments use two complementary OTS devices (A and B) that are paired to represent 1 bit. Both devices are written by currents with opposite polarities, while reading is performed with a current the same polarity. By writing the OTS pair with currents in opposite directions, the Vth values for the pair with have a difference of ΔVth=Vth_h−Vth_l, where, for example, this can be by as much as 1 V. The Vth each device will drift up over the lapse time, but ΔVth is found largely to stay the same since Vth_h and Vth_l drift at the same rate, as illustrated in FIG. 9. To meet long values of retention without refreshing, it is important to make read voltage margin ΔVth, as much as possible, irrelevant to lapse time.

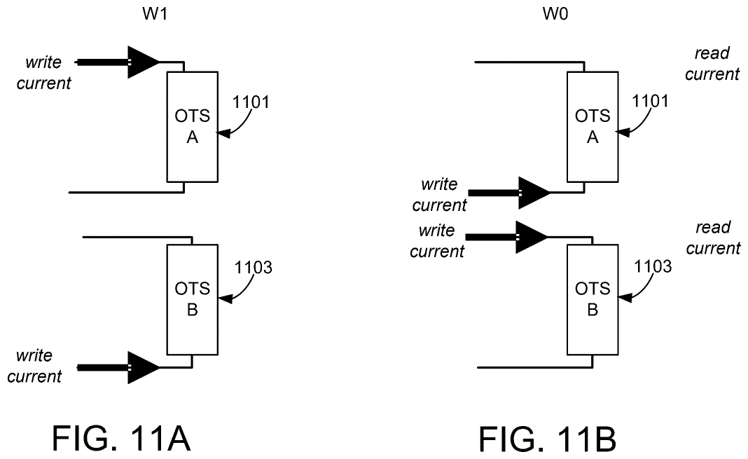

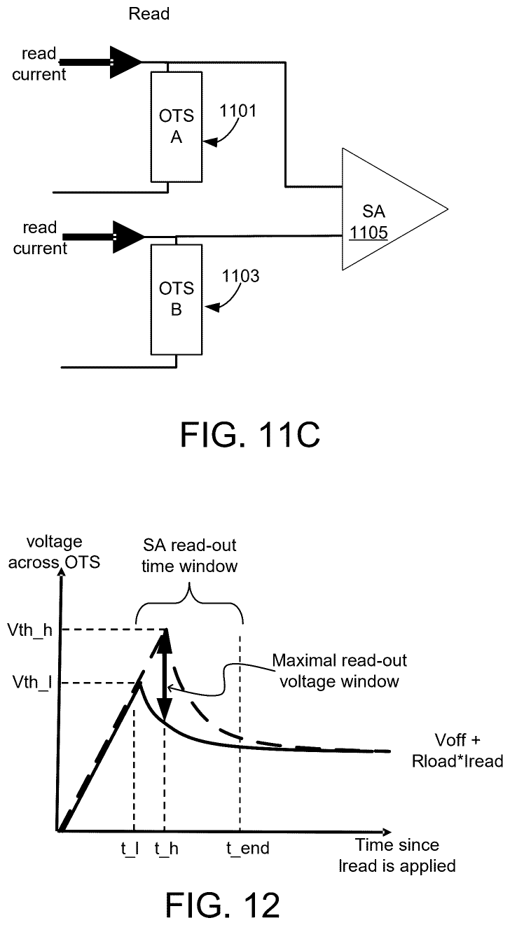

FIGS. 11A-11C illustrate the read/write configuration for self-reference read in an SOM memory the use two complimentary OTS devices (OTS A 1101, OTS B 1103) to represent 1 bit. Under this arrangement, the pair of devices are written by current with opposite directions, but read with a current in the same orientation to get either +ΔVth or −ΔVth for a demarcation read-out. The read window is independent to the lapse time since Vth drifts over the same amount of time for both OTSs in a pair.

FIGS. 11A and 11B respectively illustrate the writing of a “1” state and a “0” state in the pair of OTS A 1101 and OTS B 1103, where alternate embodiments can reverse the state assignment. As illustrated by the write current directions (i.e., polarities), a “1” in OTS A 1101 is written in the downward direction and OTS B 1103 is written in the upward direction, while to write a “0” OTS A 1101 is written in the upward direction and OTS B 1103 is written in the downward direction. FIG. 11C illustrates an embodiment for a read process where the read current is applied to both of OTS A 1101 and OTS B 1103 in the same direction, here the downward direction. Under this arrangement, one of OTS A 1101 and OTS B 1103 will have Vt_h and the other will have Vth_l, where which is which will depend on whether the pair was written to a “1” or “0”. Consequently, the sense SA 1105 will see a difference of either +ΔVth or −ΔVth between its two inputs.

In the embodiment of FIGS. 11A-11C, the data values are written using opposite current polarities in OTS A 1101 and OTS B 1103, where a “0” and a “1” are written by flipping the write direction of the OTS pair, with a read then performed by using the same polarity for both of OTS A 1101 and OTS B 1103. In an alternate set of embodiments, OTS A 1101 and OTS B 1103 could be written with the same current polarity, with both up for a “0” and both down for a “1”, or vice-versa; but then a read would be performed using opposite current polarities for OTS A 1101 and OTS B 1103. Referring again to FIGS. 11A-11B, this would correspond to flipping one the current polarities in either OTS A 1101 or OTS B 1103 for all three figures of FIGS. 11A-11C. Consequently, if one relative polarity for the pair is used to write, the other relative polarity is used to read. The following discussion uses the embodiment of FIGS. 11A-11C, but can be readily applied to the case where the relative polarities are swapped between read and write.

Considering the read-out embodiment of FIG. 11C further, each of OTS A 1101 and OTS B 1103 has a read current Ird applied separately from its upper side terminal with the same polarity, such as from one of the bit lines 1021 or 1023 of FIG. 10, or such as 606g in FIG. 6B. Under this arrangement, as the applied voltage ramps up, at Vth_l the lower threshold OTS will initially turn on, followed by the higher threshold OTS turning on when Vth_h is reached. This behavior is illustrated with respect to FIG. 12.

FIG. 12 illustrates the differential response of the two complimentary OTS devices under the read arrangement of FIG. 11C when separate read currents are used for each OTS. FIG. 12 shows the voltage across each OTS of the pair as a function of time since the read current is begun to be applied, where this voltage is a function of total read time when a constant read current is applied. As shown by the solid curve, for the low Vth device the voltage will ramp up to Vth_l at a time t_l, when the OTS will turn on and the voltage across the device will relax to the steady state on level of Voff+Rload*Iread. As shown by the broken curve for the high Vth device, the voltage will ramp up to Vth_h at a time t_h, when the OTS will turn on and the voltage across the device will relax to the steady state on level of Voff+Rload*Iread. As the voltage across both devices asymptotically approaches Voff+Rload*Iread, the difference between the two eventually becomes too small to reliably differentiate at t_end. The SA read-out time window shows time window when the sense amplifier 1105 can reliably detect that a non-zero ΔVth exists due to the difference in Vth_h and Vth_l. As illustrated by the arrow labelled maximal read out window, the maximal delta voltage occurs at t_h when the OTS with Vth_h is switched-on. Under this arrangement, a write-back is required after read. In a typical implementation, the gap between t_l and t_h is around 4ns assuming Ird=25uA, parasitic capacitance=100fF along the read path. The maximal ΔVth is greater than 1 V.

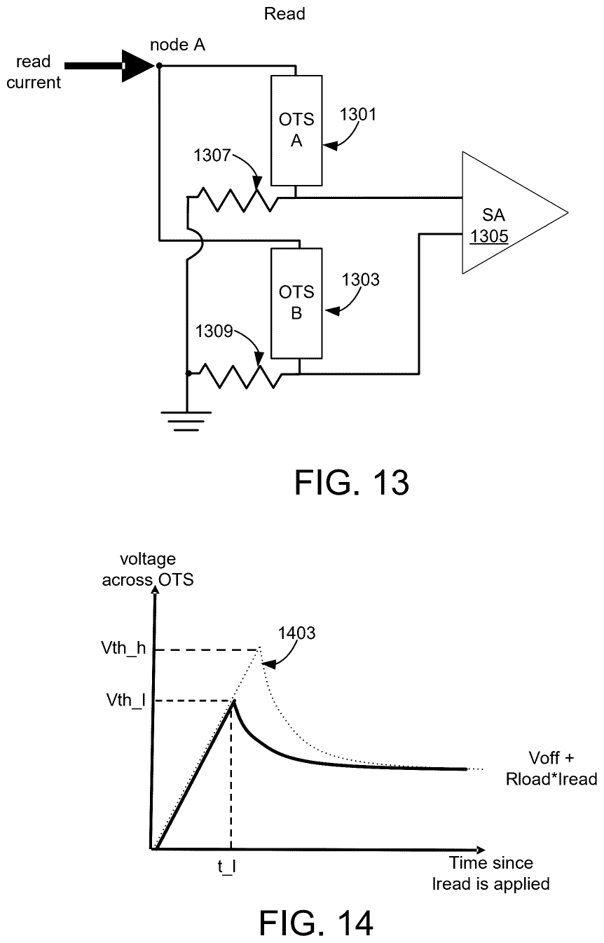

FIGS. 13 and 14 illustrate an alternate read-out embodiment in which both OTSs of a pair use the same constant read current. As shown in FIG. 13, the same constant read current is applied to both of OTS A 1301 and OTS B 1303 from the top, where on the bottom terminal OTS A 1301 and OTS B 1303 are respectively connected to ground through resistances 1307 and 1309, which have the same resistance value. When both OTSs of a memory cell pair are connected in parallel electrically, the read current will ramp up the voltage on node-A (the voltage across OTSs) until the OTS with lower Vth is switched-on. Since this applied voltage never exceeds Vth_l, the other OTS with Vth_h will not be switched on. This illustrated in FIG. 14.

FIG. 14 illustrates the voltage across the OTS pair plotted against the time since read current has started to be applied. As the voltage ramps up, once Vth_l is reached, the low threshold device turns on and the voltage across the OTS pair at node A relaxes to Voff+Rload*Iread, so that the high threshold voltage device never turns on. Consequently, as the high threshold device never turns on (as represented in the ghosted curve 1403), the sense amplifier 1305 determines the data state based on which device of the OTS pair turns on, where these is no limited SA read-out time window as in FIG. 12. Additionally, as the high threshold device never turns on, this read method eliminates the need for a write-back of the data content. Further, since the high threshold device continues to have its Vth drift upward while the low threshold device has had its Vth reset, the read margin ΔVth will increase with each read of the OTS memory cell pair.

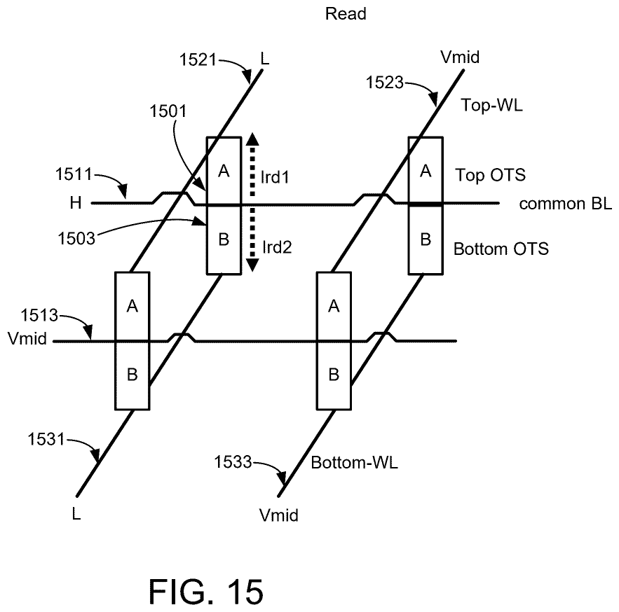

Concerning the locating of the OTS pair, they can both be part of a single layer cross-point embodiment, as in FIG. 4A, or be part of a two story cross-point embodiment, as in that of FIG. 4D. In one set of embodiments based on the read arrangement of FIG. 13, a two-level memory array as in FIG. 4D with the OTS pair each having a first terminal commonly connected at same bit line and their bottom terminals connected on the different level word line. Based on such a two-level embodiment, FIGS. 15-17B present an electrically parallel connection for each pair of OTS during the read, where the use of two stories of OTSs with a shared common bit line layer in the middle can minimize the manufacture cost.

FIG. 15 illustrates an embodiment for a read operation using a two-level, common bit line architecture for an OTS pair. The array portion of FIG. 15 shows two bit lines 1511 and 1513, a lower pair of word lines 1531 and 1533, each with a bottom OTS B of an OTS pair connected between a lower word line and a central bit line, and an upper pair of word lines 1521 and 1523, each with a top OTS A of an OTS pair connected between an upper word line and a central bit line. In the example of FIG. 15, the OTS pair is made up of upper OTS A 1501 and lower OTS B 1503. In a read operation, common word line 1511 is biased high H, both of word lines 1521 and 1531 are biased low L (i.e., ground). Referring back to FIG. 13, the read current is input along common bit line 1511 and the sense amplifier SA 1305 has its inputs connected on word lines 1521 and 1523. Unselected bit line 1513 and unselected word lines 1523 and 1533 are biased at the half-select voltage Vmid (e.g., ½ the H value). Under these bias conditions, either Ird1 through OTS A 1501 or Ird2 though OTS B 1503 is nearly zero. Consequently, at any given time during a read operation Ird1 and Ird2 flow in opposite directions from the common bit line 1511.

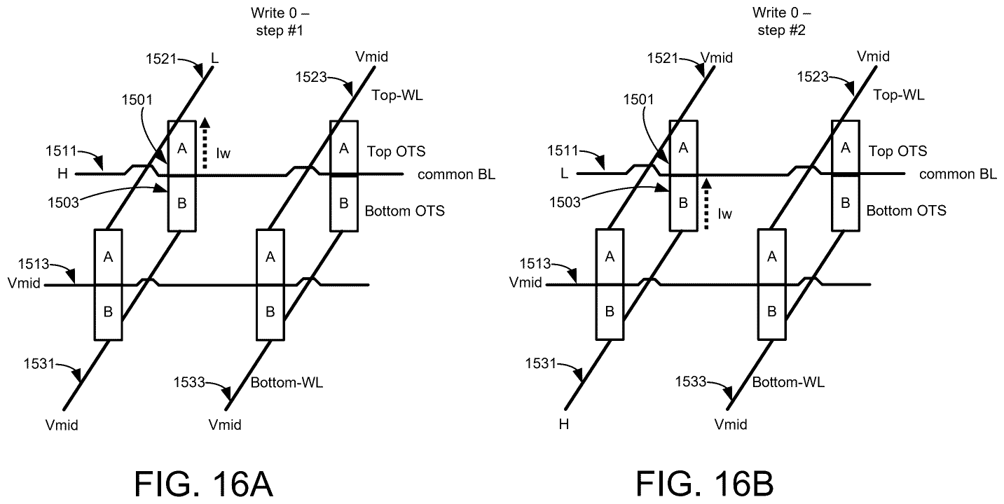

FIGS. 16A and 16B illustrate an embodiment for the two steps of writing a “0” value, in an example state assignment, in to the OTS pair of the memory cell of OTS A 1501 and OTS B 1503 in the two level cross-point array portion illustrated in FIG. 15. Both OTS A 1501 and OTS B need to be written, where this can be done in either order, and this example writes upper OTS A 1501 first. In the first step, to write a “0” state in the example embodiment here, OTS A 1501 is biased to have an upward write current Iw and OTS B 1503 is biased to have no current. To effect this, common bit line 1511 is biased high and upper word line is biased low to induce an upward flowing Iw. The other select lines (bit line 1513 and word lines 1523, 1531, and 1533) are set at the half-select Vmid voltage.

In the second step of wiring a “0” value, the lower OTS B 1503 is biased to generate an upward flowing Iw from word line 1531 at the high level and common bit line 1511 at the low voltage. The other select lines (bit line 1513 and word lines 1521, 1523, and 1533) are set at the half-select Vmid voltage. Relative to FIG. 11B, Iw for OTS B 1503 in FIG. 16B flows upward as one of the upper and lower levels of OTS devices are flipped relative to one another due the centrally located bit lines.

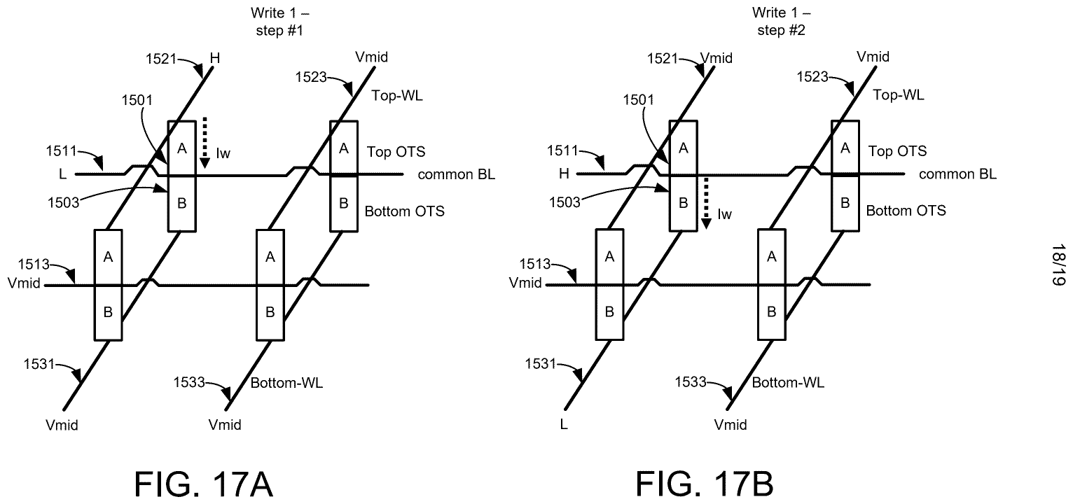

FIGS. 17A and 17B illustrate an embodiment for the two steps of writing a “1” value in to the OTS pair of the memory cell of OTS A 1501 and OTS B 1503 in the two level cross-point array portion illustrated in FIG. 15. Relative to FIGS. 16A and 16B, the process differs in that the upper OTS A 1501 and OTS B 1503 are biased in each step to induce the write current Iw to flow in the opposite direction relative to FIGS. 16A and 16B. In step 1 of FIG. 17A, the bias levels on common bit line 1511 and upper word line 1521 are reversed relative to FIG. 16A, with bit line 1511 biased at the low level and the upper word line 1521 biased at the high level, to generate a downward Iw, while the other control lines are as in FIG. 16A. In step 2 of FIG. 17B, the bias levels on common bit line 1511 and upper word line 1531 are reversed relative to FIG. 16B, with bit line 1511 biased at the high level and the lower word line 1531 biased at the low level, to generate a downward Iw, while the other control lines are as in FIG. 16B.

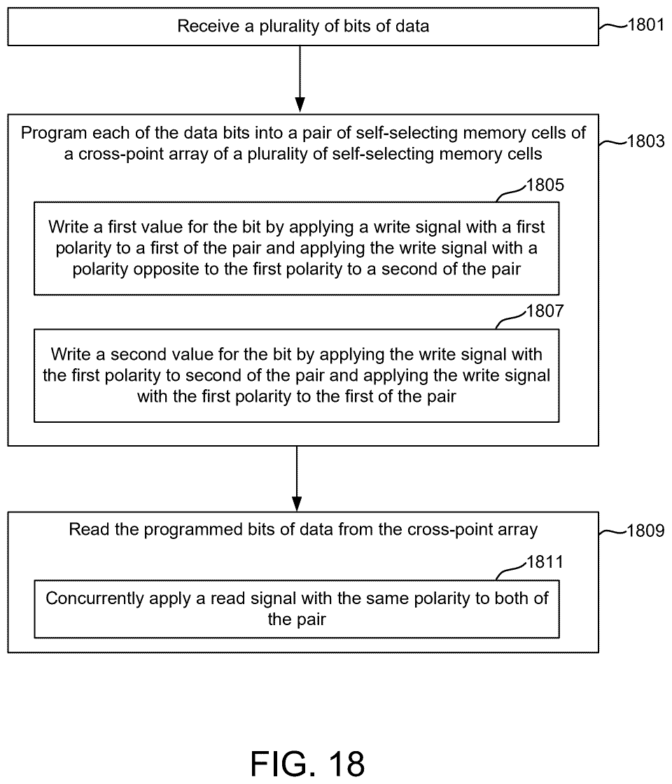

FIG. 18 is an embodiment for a method of operating a cross-point array of self-selecting memory cells that store data bits in pairs of memory cells. At step 1801 a plurality of bits of data are received, where, for example, these can be received at the memory controller 102 from a host 120 or the data may originate on the memory controller 102, such as by read the data from the memory as part of a data management operation. The data is written into the cross-point array in step 1803, with each bit written into a pair of the self-selecting memory cells. The writing of a bit is illustrated above with respect to FIGS. 11A and 11B for a general pair of OTS memory cells and with respect to FIGS. 16A, 16B, 17A, and 17B for the example of two layer cross-point array like that described above with respect to FIG. 4D. For example, to write a first bit value at step 1805, such as a “0”, as illustrated in FIG. 11B a write signal of the write current is applied at the lower terminal of OTS A 1101 and with the opposite polarity at the upper terminal of OTS B 1103. In a two layer embodiment, the writing of a “0” is illustrated by FIGS. 16A and 16B, where OTS A 1501 and OTS B are written, in either order, in two steps using opposite write current polarities, with the write current flowing out of the common bit line 1511 when writing OTS A 1501 and flowing into the common line 1511 when writing OTS B 1503. To write the other bit value (a “1” in the example) at step 1807, the polarities of the write signals to the respective members of the pair have their polarities reversed, as in FIG. 11A or FIGS. 17A and 17B.

The written data bits can then be read at step 1809 from the corresponding self-selecting memory cell pair. As noted in step 1811, this can be done by using a read signal, such as a read current, having the same polarity for both of the memory cells. For example, this can be done according to the embodiment of FIGS. 11C and 12 or the embodiment of FIGS. 13 and 14. FIG. 15 illustrates a two layer embodiment for FIG. 13, where the read current flows out of the common bit line 1511 for both of OTS A 1501 and OTS B 1503.

In view of the foregoing, it can be seen that, according to an embodiment, an apparatus comprises one or more control circuits configured to connect to a cross-point structure having self-selecting memory cells, each self-selecting memory cell having a threshold switching selector. The one or more control circuits configured to: write either a first or a second data value to each of a pair of self-selecting memory cells, where, to write one of the data values to a corresponding pair of the self-selecting memory cells, the one or more control circuits are configured to: to write the first data value, apply a write signal with a first polarity to the first of the pair of the self-selecting memory cells and apply the write signal with a second polarity to the second of the pair of the self-selecting memory cells, the second polarity having a first relative polarity with respect to the first polarity; and to write the second data value, apply the write signal with a polarity opposite the first polarity to the first of the pair of the self-selecting memory cells and apply the write signal with a polarity opposite the second polarity to the second of the pair of the self-selecting memory cells. Subsequent to writing each of the data values to the corresponding pair of self-selecting memory cells, The one or more control circuits configured to read selected ones of the written pairs of self-selecting memory cells, where, to read a selected one of the written pairs, the one the one or more control circuits are configured to: apply a read signal to each of the pair of self-selecting memory cells having a second relative polarity, the second relative polarity being opposite to the first relative polarity; and compare a voltage level at a terminal of each of the pair of self-selecting memory cells in response to the applied read signal.

An embodiment includes a method comprising: receiving a plurality of bits of data; programing each bit of the plurality of data bits into a pair of self-selecting memory cells of a cross-point array of a plurality of self-selecting memory cells by writing a first value for the bit by applying a write signal with a first polarity to a first of the pair and applying the write signal with a second polarity to a second of the pair, the second polarity having a first relative polarity with respect to the first polarity and writing a second value for the bit by applying the write signal with an opposite of the second polarity to the second of the pair and applying the write signal with the opposite of the first polarity to the first of the pair; and reading the programmed bits of data from the cross-point array, including reading the bit programmed to a selected pair of self-selecting memory cells by concurrently applying a read signal to the pair with a second relative polarity, the second relative polarity being opposite to the first relative polarity.

An embodiment includes a memory system comprising: a cross-point memory structure having a plurality of bit lines, a plurality of word lines, and a plurality memory cells, each memory cell connected at a junction of one of the bit lines and one of the word lines, each memory cell having a threshold switching selector; and one or more control circuits in communication with the cross-point memory structure and configured to program data to and to read data from the cross-point memory structure, each bit of a plurality of data bits being stored in a pair of the memory cells. To program each data bit into a pair of the memory cells the one or more control circuits are configured to: write a first value for the bit by applying a write current with a first polarity to a first of the pair and applying the write current with a second polarity having first relative polarity to a second of the pair; and write a second value for the bit by applying the write current with the first polarity to second of the pair and applying the write current with the second polarity to the first of the pair. To read a data bit from a selected pair of memory cells the one or more control circuits are configured to concurrently apply a read current with a second relative polarity different to the first relative polarity to the selected pair.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more other parts). In some cases, when an element is referred to as being connected or coupled to another element, the element may be directly connected to the other element or indirectly connected to the other element via intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

The terms “top” and “bottom,” “upper” and “lower” and “vertical” and “horizontal,” and forms thereof, as may be used herein are by way of example and illustrative purposes only, and are not meant to limit the description of the technology inasmuch as the referenced item can be exchanged in position and orientation. Also, as used herein, the terms “substantially” and/or “about” mean that the specified dimension or parameter may be varied within an acceptable tolerance for a given application.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

What is claimed is:

1. An apparatus, comprising:
one or more control circuits configured to connect to a cross-point structure having self-selecting memory cells, each self-selecting memory cell having a threshold switching selector, the one or more control circuits configured to:
write either a first or a second data value to each of a pair of self-selecting memory cells, where, to write one of the data values to a corresponding pair of the self-selecting memory cells, the one or more control circuits are configured to:
to write the first data value, apply a write signal with a first polarity to the first of the pair of the self-selecting memory cells and apply the write signal with a second polarity to the second of the pair of the self-selecting memory cells, the second polarity having a first relative polarity with respect to the first polarity; and
to write the second data value, apply the write signal with a polarity opposite the first polarity to the first of the pair of the self-selecting memory cells and apply the write signal with a polarity opposite the second polarity to the second of the pair of the self-selecting memory cells; and
subsequent to writing each of the data values to the corresponding pair of self-selecting memory cells, read selected ones of the written pairs of self-selecting memory cells, where, to read a selected one of the written pairs, the one the one or more control circuits are configured to:
apply a read signal to each of the pair of self-selecting memory cells having a second relative polarity, the second relative polarity being opposite to the first relative polarity; and
compare a voltage level at a terminal of each of the pair of self-selecting memory cells in response to the applied read signal.

2. The apparatus of claim 1, wherein each of the self-selecting memory cells has a first terminal and a second terminal, and wherein to read the selected pairs of self-selecting memory cells the one or more control circuits are configured to:
independently and concurrently apply the read signal to the first terminal of each of the pair of self-selecting memory cells; and
to the compare the voltage level at the first terminal of each of the pair of self-selecting memory cells in response to the applied read signal.

3. The apparatus of claim 2, wherein to read the selected pairs of self-selecting memory cells the one or more control circuits are configured to compare a relative voltage levels at which the first and the second of the pair of the self-selecting memory cells turn on in response to the applied write signal.

4. The apparatus of claim 1, wherein each of the self-selecting memory cells has a first terminal and a second terminal, and wherein to read the selected pairs of self-selecting memory cells the one or more control circuits are configured to:
concurrently apply the read signal from a common source to the first terminal of each of the pair of self-selecting memory cells; and
to the compare the voltage level at the second terminal of each of the pair of self-selecting memory cells in response to the applied read signal.

5. The apparatus of claim 4, wherein to read the selected pairs of self-selecting memory cells the one or more control circuits are configured to compare a relative voltage levels at which one but not the other of the first and the second of the pair of the self-selecting memory cells turn on in response to the applied write signal.

6. The apparatus of claim 1, wherein the write signal is a current and the read signal is a current.

7. The apparatus of claim 1, wherein the one or more control circuits are formed on a control die, the apparatus further comprising:
a memory die including the cross-point structure, the memory die separate from and bonded to the control die.

8. The apparatus of claim 1, further comprising:
the cross-point structure, the one or more control circuits and the cross-point structure formed on a single die.

9. The apparatus of claim 1, further comprising:
the cross-point structure, wherein each of the self-selecting memory cells is an Ovonic Threshold Switch (OTS).

10. The apparatus of claim 1, further comprising:
the cross-point structure, wherein the cross-point structure comprises:
a plurality of bit lines running in a first direction over a substrate; and
a plurality of first word lines running in a second direction over the substrate, and wherein the self-selecting memory cells includes a first plurality of memory cells each having a first terminal connected to a corresponding one of the bit lines and a second terminal connected to a corresponding one of the first word lines.

11. The apparatus of claim 10, the cross-point structure further comprising:
a plurality of second word lines running in the second direction over the substrate, the plurality of bit lines located between the plurality of first word lines and the plurality of second word lines, and wherein the self-selecting memory cells includes a second plurality of memory cells each having a first terminal connected to a corresponding one of the bit lines and a second terminal connected to a corresponding one of the second word lines.

12. The apparatus of claim 11, wherein each pair of the self-selecting memory cells comprises a first of the pair having a first terminal connected to a corresponding first bit line and a second terminal connected to a first word line and a second of the pair having a first terminal connected to the corresponding first bit line and a second terminal connected to a second word line.

13. The apparatus of claim 12, wherein to read the selected one of the written pairs of self-selecting memory cells the one or more control circuits are further configured to: apply the read signal to the corresponding first bit line.

14. A method, comprising:
receiving a plurality of bits of data;
programing each bit of the plurality of data bits into a pair of self-selecting memory cells of a cross-point array of a plurality of self-selecting memory cells by:
writing a first value for the bit by applying a write signal with a first polarity to a first of the pair and applying the write signal with a second polarity to a second of the pair, the second polarity having a first relative polarity with respect to the first polarity; and
writing a second value for the bit by applying the write signal with an opposite of the second polarity to the second of the pair and applying the write signal with the opposite of the first polarity to the first of the pair; and
reading the programmed bits of data from the cross-point array, including reading the bit programmed to a selected pair of self-selecting memory cells by:
concurrently applying a read signal to the pair with a second relative polarity, the second relative polarity being opposite to the first relative polarity.

15. The method of claim 14, wherein the write signal is a current level and the read signal is a current.

16. The method of claim 14, wherein each of the self-selecting memory cells has a first terminal and a second terminal, and wherein reading the bit programmed to the selected pair of self-selecting memory cells includes:
concurrently applying the read signal from a common source to the first terminal of each of the selected pair; and
comparing a voltage level at the second terminal of each of the pair in response to the applied read signal.

17. The method of claim 16, wherein the cross-point array comprises:
a plurality of bit lines running in a first direction over a substrate;
a plurality of first word lines running in a second direction over the substrate; and
a plurality of second word lines running in the second direction over the substrate, each pair of the self-selecting memory cells comprising a first of the pair having a first terminal connected to a corresponding first bit line and a second terminal connected to a first word line and a second of the pair having a first terminal connected to the corresponding first bit line and a second terminal connected to a second word line, wherein concurrently applying the read signal from a common source to the first terminal of each of the selected pair includes:
applying the read signal to the corresponding first bit line.

18. The method of claim 14, wherein each of the self-selecting memory cells has a first terminal and a second terminal, and wherein reading the bit programmed to the selected pair of self-selecting memory cells includes:
independently and concurrently applying the read signal the first terminal of each of the selected pair; and
comparing a voltage level at the first terminal of each of the pair in response to the applied read signal.

19. A memory system, comprising:
a cross-point memory structure having a plurality of bit lines, a plurality of word lines, and a plurality memory cells, each memory cell connected at a junction of one of the bit lines and one of the word lines, each memory cell having a threshold switching selector; and
one or more control circuits in communication with the cross-point memory structure and configured to program data to and to read data from the cross-point memory structure, each bit of a plurality of data bits being stored in a pair of the memory cells, where to program each data bit into a pair of the memory cells the one or more control circuits are configured to:
write a first value for the bit by applying a write current with a first polarity to a first of the pair and applying the write current with a second polarity having first relative polarity to a second of the pair; and
write a second value for the bit by applying the write current with the first polarity to second of the pair and applying the write current with the second polarity to the first of the pair; and
where to read a data bit from a selected pair of memory cells the one or more control circuits are configured to:
concurrently apply a read current with a second relative polarity different to the first relative polarity to the selected pair.

20. The memory system of claim 19, wherein the plurality of word lines comprises a plurality of first word lines and a plurality of second word lines, each pair of the memory cells storing a data bit comprising a first of the pair having a first terminal connected to a corresponding first bit line and a second terminal connected to one of first word lines and a second of the pair having a first terminal connected to the corresponding first bit line and a second terminal connected to one of the second word lines, wherein, to concurrently apply the read current to both of the pair, the one or more control circuits are further configured to:
apply the read current to the corresponding first bit line.
